(19) United States
(12) Patent Application Publication
(10) Pub. No.: US 2023/0271155 A1
(43) Pub. Date: Aug. 31, 2023

(54) PLASMA SYSTEM FOR PRODUCING SOLID-STATE ELECTROLYTE MATERIAL

(71) Applicant: Solid Power Operating, Inc., Louisville, CO (US)

(72) Inventors: Clint R. BICKMORE, Louisville, CO (US); Colby LANE, Fort Collins, CO (US); Zachary SPRECHER, Broomfield, CO (US); Nathan DUNLAP, Golden, CO (US)

(21) Appl. No.: 18/135,626

(22) Filed: Apr. 17, 2023

Related U.S. Application Data
(63) Continuation-in-part of application No. 17/722,242, filed on Apr. 15, 2022.
(60) Provisional application No. 63/331,701, filed on Apr. 15, 2022.
(60) Provisional application No. 63/332,634, filed on Apr. 19, 2022.
(60) Provisional application No. 63/175,187, filed on Apr. 15, 2021.

(51) Int. Cl. B01J 19/08; H01M 10/0562; C01B 35/14; C01D 15/00; C01B 25/14; H01J 37/32

(52) U.S. Cl. CPC B01J 19/088; H01M 10/0562; C01B 35/14; C01D 15/00; C01B 25/14; H01J 37/32055; H01M 2300/008; B01J 2219/0896; B01J 2219/0886; B01J 2219/0809; B01J 2219/083; B01J 2219/0869; B01J 2219/0839; C01P 2006/40; H01J 2237/327

(57) ABSTRACT

Aspects of the present disclosure involve a plasma system for practicing various methods of synthesizing solid-state electrolyte materials and precursors for solid-state electrolyte materials.

### CROSS-REFERENCE TO RELATED APPLICATIONS

This application is related to and claims priority under 35 U.S.C. § 119(e) from U.S. Provisional Patent Application No. 63/331,701 filed Apr. 15, 2022 and claims priority under 35 U.S.C. § 119(e) to U.S. Provisional Patent Application No. 63/332,634 filed Apr. 19, 2022, both of which are hereby incorporated by reference in their entirety.

This application is also related to and is a continuation-in-part of co-pending U.S. patent application Ser. No. 17/722,242 filed Apr. 15, 2022, which claims priority under 35 U.S.C. § 119(e) to U.S. Provisional Patent Application No. 63/175,187 filed Apr. 15, 2021, both of which are hereby incorporated by reference in their entirety.

### TECHNICAL FIELD

Embodiments of the present invention generally relate to plasma systems and methods for producing solid-state battery electrolyte materials and precursors for solid-state electrolyte materials.

### BACKGROUND AND INTRODUCTION

The ever-increasing number and diversity of mobile devices, the evolution of battery powered transportation including hybrid and electric automobiles, and the development of Internet-of-Things devices, among a myriad of other battery-powered devices, is driving ever greater need for battery technologies with improved reliability, capacity, thermal characteristics, lifetime and recharge performance. Currently, although lithium solid-state battery technologies offer potential increases in safety, packaging efficiency, and enable new high-energy chemistries as compared to other types of batteries, improvements in lithium battery technologies and other solid-state technologies are needed, including improvements in production efficiency and consistency.

It is with these observations in mind, among others, that various aspects of the present disclosure were conceived.

### SUMMARY

Aspects of the present disclosure involve a plasma system including a chamber containing at least one of a solid precursor or solid reactant material, the chamber may be in communication with a carrier gas line where the solid precursor or solid reactant material is mixed. The system may include an electrode assembly including a first electrode and a second electrode, the first electrode and the second electrode may be proximally positioned to form an arc therebetween to generate a plasma with a plasma chamber operably coupled with the electrode assembly. The system may include a first channel in fluid communication with the carrier gas line, the channel may be positioned to deliver carrier gas and the solid precursor or solid reactant at a controllable rate into the plasma chamber at the plasma generated therein.

In various aspects, the first electrode may define a first cylinder, and the second electrode may define a second cylinder circumferentially disposed about the first cylinder. In various additional aspects, the first channel may be defined along a cylindrical opening of the first cylinder. The system may further include a second channel that may be defined along a space between an outer surface of the first cylinder and the second cylinder may be circumferentially disposed about the first cylinder. In various aspects, the first cylindrical electrode may define a first annular electrode end positioned with a second annular electrode end and may define a circular gap therebetween, the arc between formed between the first annular electrode end and the second annular electrode end across the gap to form a toroidal plasma within the plasma chamber. In another aspect, the second channel may be in fluid communication with the gap. In various additional aspects, the first channel may direct the carrier gas and solid precursor or solid reactant through a center region that may be defined through the toroidal plasma when formed with the plasma chamber. In various additional aspects, a terminal end port of the first channel may be positioned at a center point of the circular gap. In another aspect of the present disclosure, the terminal end port may be conical.

In various aspects, the first annular electrode end may be beveled. In various aspects, the second annular electrode end may be beveled, the beveled portion of the second annular electrode end may face the beveled portion of the first annular electrode end. In another aspect of the present disclosure, at least one of the first electrode or the second electrode may be adjustably supported to alter the circular gap formed between the first annular electrode end and the second annular electrode end.

In various aspects, the plasma chamber may include at least one port oriented to direct a third gas into the chamber.

Aspects of the present disclosure may further involve a method of producing solid-state electrolyte material that comprises generating a plasma within a plasma chamber and controllably injecting a mixture of a carrier gas and solid-state electrolyte precursor powder or solid-state electrolyte reactant powder in the plasma chamber in the presence of the generated plasma to produce a solid-state electrolyte material. The method may further involve controlling at least one of a pressure of the carrier gas and a flow rate of the carrier gas, where the carrier gas is reactive or non-reactive.

The mixture may be injected through the generated plasma within the chamber and the generated plasma may be in the form of a toroid. The process occurring within the chamber may include vaporization of the solid-state electrolyte precursor powder or solid-state electrolyte reactant powder with an effective heating temperature from 70° C. to about 1200° C.

A particle size of the solid-state electrolyte precursor powder or a powder size of the solid-state electrolyte reactant powder is in a range from 1 nm to 10 mm, in various possible examples. The solid-state electrolyte precursor powder may include a lithium containing material, a phosphorus containing material, a sulfur containing material, or a halogen containing material. The lithium containing material comprises Li₂S, Li₂CO₃, or Li₂SO₄, in various possible examples. The sulfur containing material comprises elemental sulfur, Li₂S, GeS₂, or SiS₂, in various possible examples. The phosphorus containing material or the halogen containing material comprises P₄S₁₀ or P₂S₅, in various possible examples.

In other aspects, the solid-state electrolyte precursor powder comprises at least one of Li₂S, P₃N₅, B₂S₃, Li₃N, or LiX₍₁₋ₐ₎Yₐ, where X and Y include halogens selected from F, Cl, Br, and I, or pseudohalogens selected from BH₄, BF₄, OCN, CN, SCN, SH, NO, and NO₂; and where 0≤a≤1.

In other aspects, the solid-state electrolyte reactant powder comprises at least one of reactants Li₂SO₄, LiOH, P₂S₅, elemental phosphorus, H₂S, elemental sulfur, carbon, ammonium, elemental boron, LiX, or LiY, where X and Y include halogens selected from F, Cl, Br, and I, or pseudohalogens selected from BH₄, BF₄, OCN, CN, SCN, SH, NO, and NO₂.

In various possible aspects, the solid-state electrolyte reactant powder includes lithium containing reactants, phosphorus containing reactants, or sulfur containing reactants. The lithium containing reactants may include Li₂SO₄, LiOH, Li₂O, Li₂CO₃, LiNO₃, Li₃N, LiX, and LiY where X and Y include halogens selected from F, C, Br, and I, or pseudohalogens selected from BH₄, BF₄, OCN, CN, SCN, SH, NO, and NO₂. The lithium containing reactants may also include LiX₍₁₋ₐ₎Yₐ, wherein the X and Y include halogens, such as F, C, Br, or I, and/or pseudohalogens, such as BH₄, BF₄, OCN, CN, SCN, SH, NO, or NO₂ where 0≤a≤1. The phosphorus containing reactants include P₂S₅, P₂O₅, and elemental phosphorus. The sulfur containing reactants include H₂S and elemental sulfur. The reactant powder may further comprise other reactants including carbon, ammonium, and elemental boron.

In various possible aspects, the solid-state electrolyte material comprises lithium rich anti-perovskite (LiRAP) materials. In other aspects, the solid-state electrolyte material comprises lithium-boron-sulfur (LBS) materials. In yet other aspects, the solid-state electrolyte material comprises sulfide electrolyte materials that contain phosphorus and/or a halogen (LPSX Materials).

These and other aspects are discussed in more detail below.

### BRIEF DESCRIPTION OF THE DRAWINGS

The various objects, features, and advantages of the present disclosure set forth herein will be apparent from the following description of embodiments of those inventive concepts, as illustrated in the accompanying drawings. It should be noted that the drawings are not necessarily to scale and may be representative of various features of an embodiment, the emphasis being placed on illustrating the principles and other aspects of the inventive concepts. Also, in the drawings the like reference characters may refer to the same parts or similar throughout the different views. It is intended that the embodiments and figures disclosed herein are to be considered illustrative rather than limiting.

FIG. 1 is a diagram of a plasma system synthesizing solid-state electrolyte materials and precursors for solid-state electrolyte materials from solid reactants and precursors.

FIG. 2 is a schematic diagram of one example of a plasma system.

FIG. 3A is a flow chart of a process for plasma-assisted synthesis of a solid-state electrolyte material, in accordance with an embodiment of the present disclosure.

FIG. 3B is a flow chart of a process for plasma-assisted synthesis of a solid-state electrolyte precursor, in accordance with an embodiment of the present disclosure.

FIG. 4 is a computer system diagram illustrating one example of a computing system that may be involved in controlling the plasma system described herein, as well, as involved in operations of the methods described herein.

### DETAILED DESCRIPTION

Aspects of the present disclosure involve a plasma system for practicing various methods of synthesizing solid-state electrolyte materials and precursors for solid-state electrolyte materials. The synthesis is accomplished by first providing reactants or precursors, which may include preparing the precursors for plasma-processing by reducing the particle size of the reactants or precursors, and plasma-processing the prepared reactants or precursor. As used herein “precursor” refers to specific reactants or materials that are used to make solid-state electrolytes. In this sense, all precursors may be considered reactants, but not all reactants may be considered precursors.

Plasma-processing generally includes providing a plasma gas and an excitation source. The excitation source generates a plasma by applying an electric current through the plasma gas. The reactants or precursors are carried to the generated plasma by a carrier gas and are rapidly heated, causing different chemical and physical interactions and changes in morphology to occur depending on the species of the reactants or precursors. The carrier gas may be the same as or different from the plasma gas. The gas flow rate of the carrier gas, which may affect the time of the reactants or precursors in or exposed to the plasma, is related to ensuring the desired chemical and/or physical changes take place, and the implemented rate exposure time may depend on material properties including thermal conductivity, heat capacity, particle size, etc.

In some embodiments, the plasma-processing may comprise heat-treating the reactants or precursors. When the reactants or precursors pass through the plasma, the reactants or precursors may melt, crystallize, sinter, anneal or volatilize. It is also possible for glassification to take place through melting and quenching. This type of plasma-processing may be particularly useful when forming solid-state electrolytes. As used herein, the phrase “through the plasma” can mean that a particle travels through and makes contact with the plasma, or it can mean that the particle travels adjacent to the plasma. In some exemplary embodiments, the plasma may be in the shape of an extended toroid, wherein the precursors or reactants travel through the center of the toroid and do not make direct contact with the plasma. It should be understood that the plasma can take many shapes and forms and is not limited to that of a toroid or an extended toroid.

In some embodiments, the plasma-processing may comprise transformation of the reactants or precursors. The transformation generally occurs via a chemical reaction that takes place when the reactants or precursors interact with each other when flowing through the plasma. In some aspects, the plasma-processing may form a desired product as well as one or more byproducts. The byproducts may be separated after the plasma-processing by methods known in the art. In some aspects, the byproducts may include gaseous byproducts that may be vented from the plasma chamber to the atmosphere, to a ventilation hood, or to a scrubber.

In some embodiments, the plasma-processing may comprise vaporization of at least one of the reactants or precursors. In some aspects, the vaporization of at least one of the reactants or precursors may include complete ionization or atomization of the reactants or precursors. The vaporization occurs in the hottest portions of the plasma and may be followed by condensation of the resultant precursors or the solid-state electrolyte after the vaporized material has cooled.

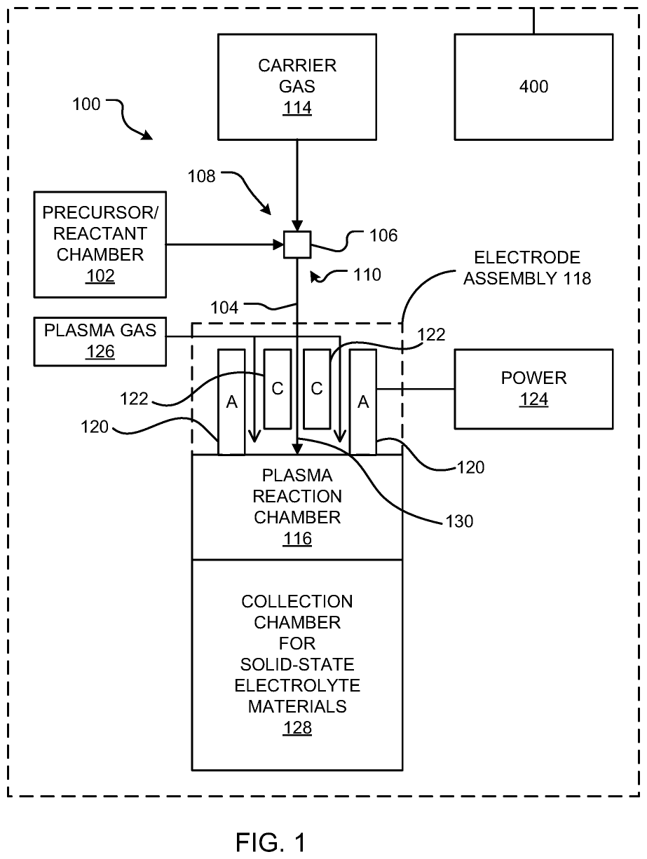

FIG. 1 is a diagram of a plasma system 100 for producing a solid-state electrolyte material or a solid-state electrolyte precursor. The system includes a chamber 102 interconnected with a feed line 104. In one example, solid-state electrolyte precursor material may be stored in the chamber 102. The precursor material may be in powder form or otherwise solid form (e.g., pellet or boule). In another example, reactants for synthesizing solid-state electrolyte precursors may be stored in the chamber 102. The reactants may be in powder form or otherwise solid form. In an alternative, or additionally, the system may include an aerosol generator in fluid communication with the feed line 104 to feed the reactants or precursors as a solution or slurry.

In some embodiments, the precursors and/or reactants may be mixed or alloyed before being stored in the chamber 102. Mixing the precursors and/or reactants may be important to forming a homogeneous composite material and ensuring the proper molar ratio of precursors is delivered to the plasma, thus resulting in a higher-purity product.

In some embodiments, the precursors and/or the reactants may undergo a particle size reduction before being stored in the chamber 102. The particle size reduction may be accomplished through various known techniques, alone or in various combinations, including milling, grinding, high shear mixing, solution processing, and thermal treating. As used herein, particle size refers to the average particle size of the powder as measured by the diameter of the particles. Methods of measuring particle size are known in the art. Smaller particles sizes are preferred, as smaller particle sizes allow for the better control of the ratio of precursors and/or reactants entering the plasma, and/or the scale of mixing.

In some embodiments, the powder may have an average particle size from about 1 nm to about 10 mm. In some aspects, the powder may have an average particle size from about 1 nm to about 50 nm, about 1 nm to about 100 nm, about 1 nm to about 250 nm, about 1 nm to about 500 nm, about 1 nm to about 750 nm, about 1 nm to about 1 μm about 1 nm to about 10 μm, about 1 nm to about 50 μm, about 1 nm to about 100 μm, about 1 nm to about 250 μm, about 1 nm to about 500 μm, about 1 nm to about 750 μm, about 1 nm to about 1 mm, about 1 nm to about 5 mm, or about 1 nm to about 10 mm.

In some embodiments, all of the precursors and/or reactants may have a uniform particle size. In other embodiments, one or more reactants may have a larger or smaller particle size as compared to the other reactants. Varying the particle size of the reactants may be advantageous when the reactants have substantially different melting points and/or boiling points. For example, a reactant particle with a low melting point and boiling point may substantially or completely evaporate before reacting with the remaining reactants if the particle size of the reactants is small. Thus, the particle size of the reactants may be modified to increase reaction yields.

The chamber 102 is operably connected with the feed line 104 by way of a valve 106. The chamber is fluidly connected at an inlet side 108 of the valve 106. The feed line 104 is fluidly connected at an opposing, e.g., outlet 110, side of the valve. The material in the chamber is introduced into the feed line at the valve 106. In one example, the feed line includes a carrier gas 114. The carrier gas 114 may be an inert gas, such as argon or helium, or other Noble gases such as neon, krypton, xenon, or may be a reactive gas, such as hydrogen sulfide, sulfur vapor, sulfur hexafluoride, water, oxygen, ozone, ammonia, nitric oxide (NO₂, N₂O₄), nitrogen gas, chlorine gas, bromine gas, iodine gas, hydrogen fluoride, hydrogen chloride, hydrogen bromide, methane, or other reactive gases involved in the process occurring within the plasma chamber 116. In some examples, air, dry or humid, alone or in combination with an inert or reactive gas may also be used. In another embodiment, the reactive carrier gas may a phosphorus-containing gas or a boron-containing gas. A non-reactive carrier gas may be considered a carrier gas that does not itself engage in chemical interactions with the precursors or reactants during processing. A reactive carrier gas may be considered a carrier gas that does chemically interact with the precursors or reactants. The carrier gas 114, in one example, is provided to the system at a controllable flow rate. The carrier gas 114 thus may be stored in a pressurized chamber that is maintained at a pressure suitable to provide a range of flow rates for any given process implemented by the plasma system 100, pumped into the system or otherwise provided at a controllable flow rate. Generally, the solid precursor or reactant material is mixed into the carrier gas stream and carried to the plasma chamber 116. In various examples, the chamber may be pressurized and/or there may be a controllable inert gas source coupled to the chamber such that material is forced into the feed line 104. Besides controlling pressure or gas flow rate, a powder injector, which may be a form of valve, may also be used to control the mixing of chamber material into the feed line 104.

The system further includes a plasma electrode body (e.g., electrode assembly 118) that includes electrodes that, when powered, form a plasma within a plasma reaction chamber 116. In one example, the arrangement of electrodes and powering of the same may be considered a plasma torch. In one example, the electrodes include an anode (−) 120 and a cathode (+) 122. The cathode 122 may define or otherwise support a feed tube 130 that is operably coupled with the feed line 104. As such, the carrier gas 114 and powder material picked-up at the valve 106 flow into the feed tube 130. The anode is positioned adjacent the cathode with a gap between the cathode and anode. Further, a plasma gas 126 may be fed between the electrodes. The plasma gas 126 may be inert or may be an active part of the targeted plasma reaction within the chamber. In any event, when a strong potential between the electrodes is generated from the power supply 124 coupled with electrodes (e.g., electrode assembly 118), a plasma is ignited within the chamber 116 at the electrodes. The power supply 124 may provide AC power, DC power, other more complex controlled signals, or may be a laser source, a radiofrequency source, a microwave source, or combinations of the same. In one example, discussed in more detail below, the system generates a toroidal-shaped plasma. The precursor and/or reactants and carrier gas 114 are injected through the feed tube 130 and through the toroidal plasma.

The plasma may be very hot on the order of 5000 Kelvin but may vary significantly depending on the specific process being performed and the precursor and/or reactant material is directed through the toroid to heat the material. To adjust the plasma reaction and/or the plasma formation, the precursor or reactant particle size and flow rate to and through the plasma may be controlled, the gap between electrodes may be controlled, and the injection rate and type of any plasma gas 126 used to ignite and/or sustain the plasma may be controlled. Excitation of the plasma, flow rate of the plasma gas 126 and/or carrier gas 114, the temperature of the plasma, and other factors may be adjusted to achieve an effective heating temperature from about 70° C. to about 1200° C. As used herein “effective heating temperature” refers to the average temperature of the particles flowing through the plasma, rather than the temperature of the plasma itself. Generally speaking, there are several processes that may occur including: heat treatment (material passes through the plasma and is heated according to residence time, plasma temperature, material properties (e.g., heat capacity and thermal conductivity); material transformation (e.g., reaction of materials or components thereof to form a product); and vaporization and condensation (e.g., complete ionization or complete atomization).

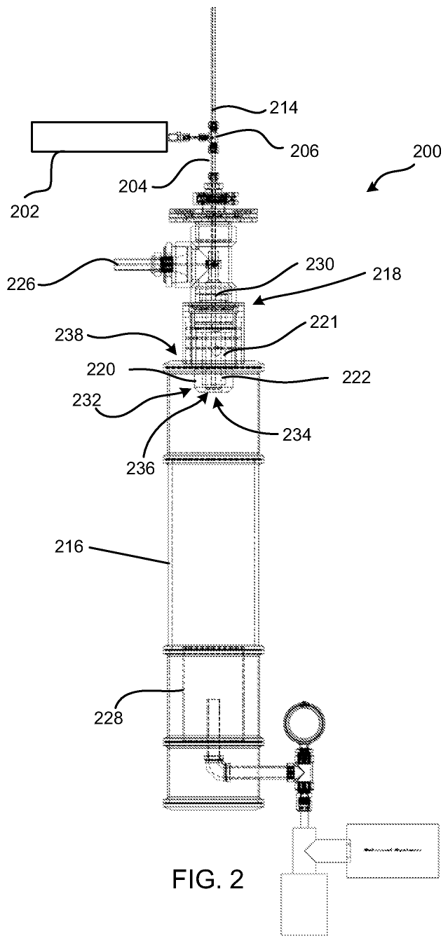

FIG. 2 is a section diagram of one example of a plasma system 200 for synthesizing a solid-state electrolyte. As discussed with respect to FIG. 1, the system of FIG. 2 similarly includes a powder chamber 202 operably coupled with feed line 204 that introduces a carrier gas 214. The powder is carried to a plasma reaction chamber 216 where a plasma torch 218 ignites and sustains a plasma that acts on the powder material, along with any other materials that may be provided, to synthesize a target material that is collected in a collection chamber 228 positioned to collect material from the reaction chamber 216.

In some embodiments, the powder material may include one or more solid-state electrolyte precursors. In other embodiments, the powder material may include one or more reactants for synthesizing solid-state electrolyte precursors.

The powder chamber 202 holds powder material, which may be in some solid form having an average particle size from about 1 nm to about 10 mm, or other ranges discussed above. A valve 206 may be positioned at the feed line 204 to control mixing of chamber material into the feed line 204. In one example, the valve 206 may include a Bernoulli valve. In another example, the valve 206 may include a Venturi valve. In either case, a relatively low-pressure area is formed at the valve 206 by way of the carrier gas 214 flowing past an inlet of the powder chamber 202 at the valve 206. By way of the low pressure, powder is pulled from the chamber 202 into the feed line 204 and the carrier gas 214 carries the gas toward the plasma chamber 216. Regardless of the mechanism, material from the powder chamber 202 is mixed into the feed line 204 and carried by the gas to the plasma chamber 216.

In the example of FIG. 2, the feed line 204 is in fluid communication with a feed tube 230 defined in an electrode, which in this case is a cathode 222. Here, the cathode 222 is cylindrical and defines a feed channel along a longitudinal centerline of the cylinder. A power supply is coupled with the cathode 222 to energize the cathode 222 to ignite and sustain a plasma. A second electrode, in this case an anode 220, also defines a cylinder and is concentrically mounted such that the cylindrical cathode 222 is positioned within the cylindrical anode 220. The anode 220 and cathode 222 are mounted such that a cylindrical channel 221 may also be formed between an outer wall of the cathode 222 and an inner wall of the anode 220, in some embodiments. In this arrangement, precursor powder and a carrier gas are conveyed to the system through the feed tube 230 and an additional gas, alone or with other material, may be provided through the cylindrical channel.

In some embodiments, the carrier gas may have a flow rate of at least about 0.1 liters per minute per gram of precursors being plasma-processed. In some aspects, the carrier gas may have a flow rate of at least about 0.1, at least 0.2, at least 0.3, at least 0.4, at least 0.5, at least 0.6, at least 0.7, at least 0.8, at least 0.9, at least 1.0, at least 2.0, at least 3.0, at least 4.0, at least 5.0, at least 6.0, at least 7.0, at least 8.0, at least 9.0, or at least 10.0 liters per minute per gram of precursors being plasma-processed.

In additional embodiments, the carrier gas may have a flow rate from about 0 to about 100 liters per minute. In some aspects, the carrier gas may have a flow rate from about 0 liters per minute to about 10 liters per minute, about 0 liters per minute to about 20 liters per minute, about 0 liters per minute to about 30 liters per minute, about 0 liters per minute to about 40 liters per minute, about 0 liters per minute to about 50 liters per minute, about 0 liters per minute to about 60 liters per minute, about 0 liters per minute to about 70 liters per minute, about 0 liters per minute to about 80 liters per minute, about 0 liters per minute to about 90 liters per minute, about 10 liters per minute to about 100 liters per minute, about 20 liters per minute to about 100 liters per minute, about 30 liters per minute to about 100 liters per minute, about 40 liters per minute to about 100 liters per minute, about 50 liters per minute to about 100 liters per minute, about 60 liters per minute to about 100 liters per minute, about 70 liters per minute to about 100 liters per minute, about 80 liters per minute to about 100 liters per minute, about 90 liters per minute to about 100 liters per minute, about 10 liters per minute liters per minute to about 20 liters per minute, about 20 liters per minute to about 30 liters per minute, about 30 liters per minute to about 40 liters per minute, about 40 liters per minute to about 50 liters per minute, about 50 liters per minute to about 60 liters per minute, about 60 liters per minute to about 70 liters per minute, about 70 liters per minute to about 80 liters per minute, about 80 liters per minute to about 90 liters per minute, or about 90 liters per minute to about 100 liters per minute. In some aspects, the carrier gas may have a flow rate of greater than 0 liters per minute. In some additional aspects, the carrier gas may have a flow rate of greater than 100 liters per minute.

In some embodiments, the carrier gas pressure may be from about 1×10⁻⁹ Torr to about 7600 Torr. In some aspects, the carrier gas pressure may be from about 1×10⁻⁹ Torr to about 1×10⁻⁸ Torr, about 1×10⁻⁹ Torr to about 1×10⁻⁷ Torr, about 1×10⁻⁹ Torr to about 1×10⁻⁶ Torr, about 1×10⁻⁹ Torr to about 1×10⁻⁵ Torr, about 1×10⁻⁹ Torr to about 1×10⁻⁴ Torr, about 1×10⁻⁹ Torr to about 1×10⁻³ Torr, about 1×10⁻⁹ Torr to about 1×10⁻² Torr, about 1×10⁻⁹ Torr to about 1×10⁻¹ Torr, about 1×10⁻⁹ Torr to about 1 Torr, about 1×10⁻⁹ Torr to about 10 1×10⁻⁹ Torr, about 1×10⁻⁹ Torr to about 100 Torr, about 1×10⁻⁹ Torr to about 500 Torr, about 1×10⁻⁹ Torr to about 1000 Torr, about 1×10⁻⁹ Torr to about 5000 Torr, about 1×10⁻⁸ Torr to about 7600 Torr, about 1×10⁻⁷ Torr to about 7600 Torr, about 1×10⁻⁶ Torr to about 7600 Torr, about 1×10⁻⁵ Torr to about 7600 Torr, about 1×10⁻⁴ Torr to about 7600 Torr, about 1×10⁻³ Torr to about 7600 Torr, about 1×10⁻² Torr to about 7600 Torr, about 1×10⁻¹ Torr to about 7600 Torr, 1 Torr to about 7600 Torr, about 10 Torr to about 7600 Torr, about 100 Torr to about 7600 Torr, about 500 Torr to about 7600 Torr, about 1000 Torr to about 7600 Torr, about 5000 Torr to about 7600 Torr, about 1 Torr to about 1000 Torr, about 10 Torr to about 1000 Torr, about 100 Torr to about 1000 Torr, about 500 Torr to about 1000 Torr, about 1 Torr to about 500 Torr, about 10 Torr to about 500 Torr, or about 100 Torr to about 500 Torr. In some embodiments, the carrier gas pressure may be greater than 7600 Torr.

The electrodes 220,222 are mounted in and otherwise supported within a housing. In one specific example, both electrodes (the anode and the cathode) are graphite. One advantage of using graphite is that any residue from the arc is only carbon or carbon reactant. In some instances, other electrode materials may produce materials, such as transition metals, that interfere with the plasma synthesis in the chamber. The electrodes 220,222 may be positioned and mounted within the housing in fixed relation to each other. Alternatively, either or both electrodes may be adjustably mounted such that one or both may be moved relative to the other. The electrodes 220,222 extend to an opening into the plasma chamber 216 such that a plasma may be formed and maintained therein. The electrodes 220,222 are positioned such that there is a gap 232 defined by ends of the electrodes 220,222 at a terminus 234 of the cylindrical channel at the plasma chamber 216. In the example of cylindrical electrodes, the gap 232 is formed between an inner cylindrical (or circular) end of the inner cathode 222 and an outer cylindrical (or circular) end of the outer anode 220. As such, the gap 232 is circular. Moreover, the cylindrical channel terminates at the gap 232 such that any gas or other material conveyed through the cylindrical channel flows through the gap 232 between the electrodes 220,222 and will be exposed to any arc formed between the electrodes 220,222 when energized. By adjustably mounting either or both of the anode 220 and cathode 222, the gap 232 dimension (e.g., separation distance) may be adjusted to thereby control the plasma.

As introduced, either or both electrodes 220,222 may be adjustably supported in the housing to alter the relative positioning of the anode 220 to the cathode 222, which may accordingly alter the circular gap 232 between each, alter the relative positioning of the feed tube 230 to the gap 232 and the plasma chamber 216, alter an injection angle of the plasma gas 226 into the plasma chamber 216 and with respect to the material and carrier gas 214 flowing into plasma chamber 216 from the feed tube 230, and/or other parameters. In one example, the inner cathode 222 is fixedly mounted within the housing, and the outer anode 220 is movably mounted. In this example, the anode 220 is supported in a tubular member with a threaded portion that is received in an annular threaded portion of the housing. Rotation of the tubular member may move the anode relative to the cathode 222 supported within to thereby adjust the relationship therebetween.

Referring to the inner electrode 222 (e.g., the cathode), it can be seen that the feed tube 230 defined along the longitudinal centerline of the cylindrical cathode terminates at an expanding radius conical opening 236 (aperture) at the end of the feed tube opening into the plasma chamber 216. The outer cylindrical wall of the cathode 222 at the same end, facing the anode 220, is beveled. In one example, the bevel forms a 45-degree angle between the outer cylindrical wall of the cathode 222 and an end circular wall facing the plasma chamber 216. Other angles or no beveling are also possible. The anode 220 defines a first cylindrical inner wall of a greater diameter than the outer wall of the cathode 222 thereby forming the cylindrical channel therebetween when the cathode 222 is positioned within the anode 220. At the end area of the cathode 222 at the plasma chamber 216, the inner wall of the anode 220 is also beveled at a matching 45-degree angle to the bevel of the cathode 222, with the beveled faces generally parallel and facing each other. As can be seen, the outer beveled face is slightly longer than the inner beveled face providing additional adjustability between the electrodes to control formation of the arc. The anode 220 defines a cylindrical opening positioned below and of a greater diameter than the bottom face of the cathode 222. The conical feed tube opening injects material into an annular space defined within the cylindrical opening of the anode 220, below the circular wall of the anode 220 and including the channel where additional gases may be injected and which defines the energy gap 232 between the anode 220 and the cathode 222 to form a plasma.

A plasma reaction chamber 216 is positioned at the electrodes 220,218 and to receive the material from the feed tube 230. The plasma is ignited within the reaction chamber 216 adjacent the electrodes 220,222. In the example of FIG. 2, the reaction chamber 216 is a cylindrical glass container. The container may be sealed and evacuated or otherwise maintained under vacuum during a reaction. The container defines an opening 238 at which the electrodes 220,222 are positioned. In the case of cylindrical electrodes discussed with reference to FIG. 2, a toroidal plasma is formed, and the toroid defines an inner opening (eye) that is aligned with the conical opening 236 of the feed tube 230. In this way, the precursor material passes through the opening and through the toroidal plasma.

A plasma gas 226 may also be introduced in the system and through the gas channel defined between the electrodes 220,222. In one example, the plasma gas 226 relatively uniformly flows through the cylindrical channel and passes through the circular gap formed between the electrodes. When the electrodes 220,222 are energized, the plasma gas 226 is ignited into a toroidal thermal plasma with its eye defined at the opening 236 of the feed tube 230. As mentioned above, adjusting the relative position between the anode 220 and cathode 222 may change the shape and spacing between the anode and the cathode at the gap, which may affect the formation of the plasma. When plasma gas 226 flows through the gap 232 between the electrodes 220,222 and the electrodes 220,222 are energized, a plasma may be formed and sustained.

Generally speaking, there are two gasses that pass through the electrode assembly. One is the plasma gas that passes between the anode and cathode. The second is the carrier gas that carries the particles through the electrode assembly. These gasses are independently controllable. The plasma gas can be optimized to create the hot zone. This is coupled with the power supply settings for total power. The carrier gas flow rate sets the particle velocity. This gas can contribute to the plasma. This gas may be the same as the plasma gas, or it can be different. Additional gasses, through the injection ports mentioned below, can be added to the chamber to supply cooling or a reactive component into the chamber. The late-stage addition can put a reactive shell onto the particles to enable a surface treatment. The focus here is to provide ambient stability to the material.

Additionally, injection ports (not shown) may be defined in the plasma reaction chamber 216 where various gases may be introduced. In one example, the plasma chamber 216 includes a relatively planar “lid” defining an aperture at which the electrodes 220,222 and related components of the plasma torch assembly 218 are positioned. The lid may be secured to the electrode housing. Various ports may be defined in the lid and through which various gases may be introduced into the plasma chamber 216. The injection ports may be oriented to inject gas into a desired location within the chamber. For example, the port (or ports as the case may be), may be oriented to direct gas into the eye of the toroid as opposed to outside the toroid or into the toroid.

In some embodiments, the electrode housing, or more particularly the electrodes 220,222, may be cooled. In the illustrated embodiment, the housing supporting the electrodes 220,222 is a generally cylindrical structure defining a cavity in which various components including the electrodes are positioned. A liquid cooling coil (not shown) may be wound around the housing thereby cooling the housing, components within the housing, and any components in contact with the housing. In another example, one or more cooling fans may be positioned to move air through the housing to cool the electrodes 220,222 and other components.

In some embodiments, the plasma-processing may comprise heat-treating the reactants or precursors. When the reactants or precursors pass through the plasma, the reactants or precursors may melt, crystallize, sinter, or volatilize. This type of plasma-processing may be particularly useful when forming solid-state electrolytes.

In some embodiments, the plasma-processing may comprise transformation of the reactants or precursors. The transformation generally occurs via a chemical reaction that takes place when the reactants or precursors interact with each other when flowing through the plasma. In some aspects, the plasma-processing may form a desired product as well as one or more byproducts. The byproducts may be separated after the plasma-processing by methods known in the art. In some aspects, the byproducts may include gaseous byproducts that may be vented from the plasma chamber to the atmosphere, to a ventilation hood, or to a scrubber.

In some embodiments, the plasma-processing may comprise vaporization of at least one of the reactants or precursors. In some aspects, the vaporization of at least one of the reactants or precursors may include complete ionization or atomization of the reactants or precursors. The vaporization occurs in hottest portions of the plasma and may be followed by condensation of the reactants or precursors after the vaporized material has cooled.

In some embodiments, the plasma system may be used to produce solid-state electrolyte materials that may be incorporated into a solid-state electrochemical cell.

In some aspects, the solid-state electrolyte materials may include lithium rich anti-perovskite (LiRAP) materials. The LiRAP materials may include, but are not limited to Li₃OCl and Li₃OBr. In some aspects, the solid-state electrolyte materials may include sulfide electrolyte materials, such as but not limited to lithium-boron-sulfur (LBS) materials. In some aspects, the LBS materials may include, but are not limited to Li₃BS₃, Li₂B₂S₅, Li₅B₇S₁₃, and Li₉B₁₉S₃₃.

In additional aspects, the solid-state electrolyte materials may include sulfide electrolyte materials that contain phosphorus and/or a halogen (LPSX Materials). In some aspects, the LPSX materials may include, but are not limited to Li₆PS₅Cl, Li₆PS₅Br, Li₆PS₅Cl_{0.5}Br_{0.5}, Li₇P₂S₈Cl, Li₇P₂S₈Br, Li₇P₂S₈I, Li₇P₂S₈Cl_{0.5}Br_{0.5}, Li_{7-a-b}PS_{6-(a+b)}XₐY_{b} or Li₇P₂S₈XₐY_{b}, where X and Y includes a halogen, such as F, Cl, Br, or I or pseudohalogens, such as BH₄, BF₄, OCN, CN, SCN, SH, NO, or NO₂ where 0≤a≤2 and 0≤b≤2.

In some embodiments, the plasma system may be used to produce precursors. Precursors are materials that are later converted to solid-state electrolyte materials. In some aspects, the precursors may include Li₂S, P₃N₅, B₂S₃, Li₃N, or LiX₍₁₋ₐ₎Yₐ, where X and Y include halogens, such as F, C, Br, or I, and pseudohalogens, such as BH₄, BF₄, OCN, CN, SCN, SH, NO, or NO₂ where 0≤a≤1.

In embodiments where the plasma system is used to produce precursors, the powder may comprise reactants such as Li₂SO₄, LiOH, P₂S₅, elemental phosphorus, H₂S, elemental sulfur, carbon, ammonium, elemental boron, LiX, or LiY, where X and Y include halogens, such as F, C, Br, or I, and pseudohalogens, such as BH₄, BF₄, OCN, CN, SCN, SH, NO, or NO₂ where 0≤a≤1.

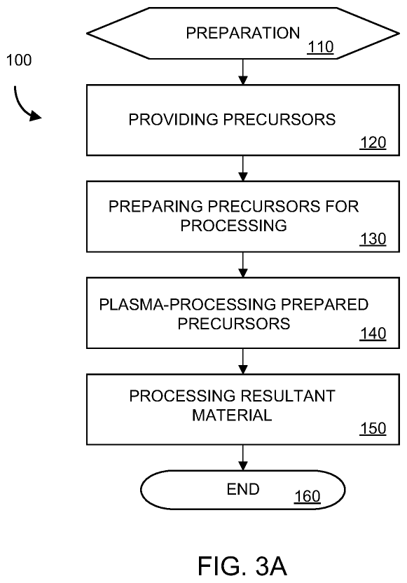

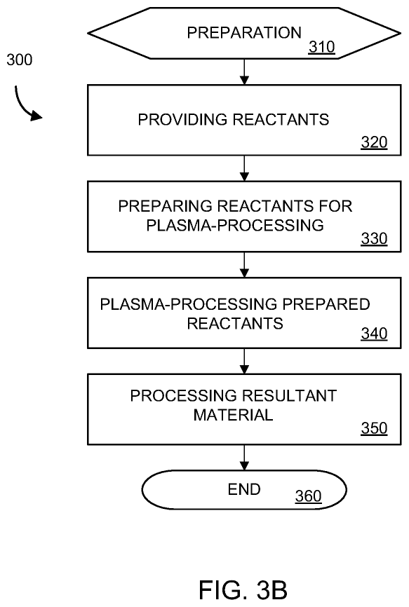

FIG. 3A is a flow chart of a process for plasma-assisted synthesis of solid-state electrolyte materials useful for the construction of secondary (e.g., rechargeable) electrochemical battery cells. Process 100, for example, results in highly lithium-ion-conducting crystalline, glass, and/or glass ceramic materials useful as solid-state electrolytes in lithium-based solid-state electrochemical cells. Process 100 may begin with preparation step 110 wherein any preparation action, such as precursor synthesis, purification, and equipment preparation may take place. It should be recognized that some preprocessing may also occur in a separate process from the plasma-process and such processed materials used in the method.

After any initial preparation or otherwise access to prepared materials, process 100 involves operation 120 where one or more precursors may be provided in amounts by weight and/or molar volume. Solid-state electrolyte precursors may include at least one lithium containing material. In some embodiments, the solid-state electrolyte precursors may further include at least one phosphorus containing material, at least one sulfur containing material, at least one halogen containing material, or combinations thereof.

In some embodiments, the lithium containing material may be or may comprise one or more of Li₂S, Li₂O, Li₂CO₃, Li₂SO₄, LiNO₃, Li₃N, Li₂NH, UGH, LiNH₂, LiF, LiCl, LiBr, or LiI. In preferred embodiments, the lithium containing material is one or more of Li₂S, Li₂CO₃, or Li₂SO₄.

In some embodiments, the phosphorous containing materials may be at least one a phosphorous sulfide material, such as P₄Sₓ where 3≤x≤10, or more specifically P₄S₄, P₄S₅, P₄S₆, P₄S₇, P₄S₈, P₄S₉, or P₄S₁₀ (P₂S₅). In another embodiment, the phosphorous containing materials may be at least one a phosphorus nitrogen compound, for example, but not limited to, P₃N₅. In another embodiment, the phosphorous containing materials may be at least one a phosphorus oxygen compound, for example but not limited to P₂O₅. In still other embodiments, the phosphorous containing material may be or may comprise elemental phosphorous. In a preferred embodiment, the phosphorous containing material is P₄S₁₀ (P₂S₅) or comprises P₄S₁₀ (P₂S₅).

In some embodiments, the sulfur containing material may be or may comprise one or more of an alkali sulfide for example, but not limited to Li₂S, Na₂S, or K₂S. In another embodiment, the sulfur containing material may be one or more of an alkaline earth sulfide for example, but not limited to BeS, MgS, CaS, SrS, or BaS. In another embodiment, the sulfur containing material may one or more of a transition metal sulfide for example, but not limited to TiS₂, ZrS₂, WS₂, FeS₂, NiS₂, CuS₂, AgS, or ZnS. In another embodiment, the sulfur containing material may be one or more of a post-transition metal sulfide for example, but not limited to Al₂S₃, Ga₂S₃, SnS₂, or Sn₂S₃. In another embodiment, the sulfur containing material may be one or more of a metalloid sulfide for example, but not limited to B₂S₃, SiS₂, GeS₂, Sb₂S₃, or Sb₂S₅. In some embodiments, the sulfur containing material may be or may comprise elemental sulfur. In preferred embodiments, the sulfur containing material is or may comprise one or more of Li₂S, GeS₂, and SiS₂.

In some embodiments, the halogen containing material may be or may comprise one or more of a lithium halide, such as LiF, LiCl, LiBr, or LiI. In another embodiment, the halogen containing material may be one or more of a sodium halide, such as NaF, NaCl, NaBr or NaI. In another embodiment, the halogen containing material may be one or more of a boron halide, for example, but not limited to BCl₃, BBr₃₃, BI₃. In another embodiment, the halogen containing material may be or may comprise one or more of an aluminum halide, for example, but not limited to AlF₃, AlBr₃, AlI₃, or AlCl₃. In another embodiment, the halogen containing material may be or may comprise one or more of a silicon halide, for example, but not limited to SiF₄, SiCl₄, SiCl₃, Si₂Cl₅, SiBr₄, SiBrCl₃, SiBr₂Cl₂, or SiI₄. In another embodiment, the halogen containing material may be or may comprise one or more of a phosphorus halide, for example, but not limited to PF₃, PF₅, PCl₃, PCl₅, POCl₃, PBr₃, POBr₃, PI₃, P₂Cl₄, P₂I₄. In another embodiment, the halogen containing material may be or may comprise one or more of a sulfur halide, for example, but not limited to SF₂, SF₄, SF₆, S₂F₁₀, SCl₂, S₂Cl₂, or S₂Br₂. In another embodiment, the halogen containing material may be or may comprise one or more of a germanium halide, for example, but not limited to GeF₄, GeCl₄, GeBr₄, GeI₄, GeF₂, GeCl₂, GeBr₂, or GeI₂. In another embodiment, the halogen containing material may be or may comprise one or more of an arsenic halide, for example, but not limited to AsF₃, AsCl₃, AsBr₃, AsI₃, AsF₅. In another embodiment, the halogen containing material may be or may comprise one or more of a selenium halide for example, but not limited to SeF₄, SeFe₆, SeCl₂, SeCl₂, Se₂Br₂, or SeBr₄; tin halide for example, but not limited to SnF₄, SnCl₄, SnBr₄, SnI₄, SnF₂, SnCl₂, SnBr₂, or SnI₂. In another embodiment, the halogen containing material may be or may comprise one or more of an antimony halide for example, but not limited to SbF₃, SbCl₃, SbBr₃, SbI₃, SbF₅, SbCl₅, In another embodiment, the halogen containing material may be or may comprise one or more of a tellurium halide for example, but not limited to TeF₄, Te₂F₁₀, TeF₆, TeCl₂, TeCl₄, TeBr₂, TeBr₄, or TeI₄. In another embodiment, the halogen containing material may be or may comprise one or more of a lead halide for example, but not limited to PbF₄, PbCl₄, PbF₂, PbCl₂, PbBr₂, or PbI₂. In another embodiment, the halogen containing material may be or may comprise one or more of a bismuth halide for example, but not limited to BiF₃, BiCl₃, BiBr₃, or BiI₃. In another embodiment, the halogen containing material may be or may comprise one or more of an yttrium halide for example, but not limited to YF₃, YCl₃, YBr₃, or YI₃. In another embodiment, the halogen containing material may be or may comprise one or more of a magnesium halide for example, but not limited to MgF₂, MgCl₂, MgBr₂, or MgI₂. In another embodiment, the halogen containing material may be or may comprise one or more transition metal halides. In another embodiment, the halogen containing material may be or may comprise one or more of a zirconium halide for example, but not limited to ZrF₄, ZrCl₄, ZrBr₄, or ZrI₄. In another embodiment, the halogen containing material may be or may comprise one or more lanthanide halides. In another embodiment, the halogen containing material may be or may comprise one or more of a lanthanum halide for example, but not limited to LaF₃, LaCl₃, LaBr₃, or LaI₃. In preferred embodiments, the halogen containing material is one or more of LiF, LiCl, LiBr, or LiI.

In some embodiments, the halogen containing material may comprise one or more pseudohalogens. In some embodiments, pseudohalogens may include BH₄, BF₄, OCN, CN, SCN, SH, NO, or NO₂. In some embodiments, the halogen containing material may include LiBH₄, LiBF₄, LiOCN, LiCN, LiSCN, LiSH, LiNO, or LiNO₂. In some embodiments, the halogen containing material may include NaBH₄, NaBF₄, NaOCN, NaCN, NaSCN, NaSH, NaNO, or NaNO₂.

In some aspects, the halogen containing material may be or may comprise a compound having the general formula LiX₍₁₋ₐ₎Yₐ, wherein the X and Y include halogens, such as F, C, Br, or I, and/or pseudohalogens, such as BH₄, BF₄, OCN, CN, SCN, SH, NO, or NO₂ where 0≤a≤1.

In operation 130, the precursors may be prepared for plasma processing by way of mixing, solution processing, alloying, and/or by various particle-size reduction techniques, alone or in various possible combinations, including milling, grinding, high shear mixing, thermal treating and other methods to reduce the particle size of the precursors. Mixing the precursors is critical to forming a homogeneous composite material and ensuring the proper molar ratio of precursors is delivered to the plasma, thus resulting in a higher-purity product. Precursor particle size may include a range of 1 nm to 10 mm, with various ranges of sizes discussed above. As used herein, “particle size” refers to the average particle size as measured by the diameter of the particles. Methods of measuring particle size are known in the art. Smaller particle sizes are preferred, as smaller particle sizes allow for better control of the ratio of reactants entering the plasma chamber. The particle size of at least one of the precursors may be reduced prior to plasma-processing. In some embodiments, the particle size of all of the precursors may be reduced prior to plasma processing. In some embodiments, operation 130 is performed without any chemical reactions occurring. In other embodiments, some chemical reactions may occur in operation 130.

In some embodiments, after particle-size reduction, the precursors may have a particle size from about 1 nm to about 10 mm. In some aspects, the precursors may have a particle size from about 1 nm to about 50 nm, about 1 nm to about 100 nm, about 1 nm to about 250 nm, about 1 nm to about 500 nm, about 1 nm to about 750 nm, about 1 nm to about 1 μm about 1 nm to about 10 μm, about 1 nm to about 50 μm, about 1 nm to about 100 μm, about 1 nm to about 250 μm, about 1 nm to about 500 μm, about 1 nm to about 750 μm, about 1 nm to about 1 mm, about 1 nm to about 5 mm, or about 1 nm to about 10 mm. In some additional aspects, the precursors may have a particle size from about 1 nm to about 50 nm, about 50 nm to about 100 nm, about 100 nm to about 250 nm, about 250 nm to about 500 nm, about 500 nm to about 750 nm, about 750 nm to about 1 μm, about 1 μm to about 10 μm, about 10 μm to about 50 μm, about 50 μm to about 100 μm, about 100 μm to about 250 μm, about 250 μm to about 500 μm, about 500 μm to about 750 μm, about 750 μm to about 1 mm, about 1 mm to about 5 mm, or about 5 mm to about 10 mm.

In some embodiments, all of the precursors may have a uniform particle size. Any of the particles described herein may be spherical, spheroidal, ellipsoidal, cylindrical, polyhedral, cube shaped, rod shaped, disc shaped, or irregularly shaped. In other embodiments, one or more precursors may have a larger or smaller particle size as compared to the other precursors. Varying the particle size of the precursors may be advantageous when the precursors have substantially different melting points and/or boiling points. For example, a precursor particle with a low melting point and boiling point may substantially or completely evaporate before reacting with the remaining precursors if the particle size of the precursor is small. Thus, the particle size of the precursors may be modified to increase reaction yields.

In some embodiments, the processing in operation 130 may occur in a solvent-free environment, i.e., the mixing, milling, grinding, alloying, high shear mixing, thermal treating, or other methods to reduce the particle size of the precursors is performed in the absence of a solvent. This results not only in a solvent-free process, but also ensures that the end product is free of any solvent as well. As defined herein, “solvent-free” means that there is no solvent or essentially no solvent used in the process or present in the product produced from the process. Solvent-free may also mean in the absence of a slurry and/or without requiring the formation of a slurry. Solvent-free also may mean substantially free of any solvent impurities (e.g., less than or equal to 30%, 25%, 20%, 15%, 10%, 5%, 4%, 3%, 2%, 1%, or 0.5% of any solvent-related impurities). The term “material” may be used interchangeably with “composition of matter.”

In other embodiments, the processing in operation 130 occurs in the presence of a solvent. As used herein, the term “solvent” can refer to a liquid that dissolves one or more components of a mixture, or it may refer to a liquid that acts as a carrier fluid and does not dissolve any components of a mixture. In some aspects, the solvent may be an aprotic solvent. In some aspects, the solvent may be a protic solvent. In some particular aspects, the solvent may be a non-polar hydrocarbon, including but not limited to benzene, toluene, xylenes, C₁-C₁₂ alkanes (including substituted or unsubstituted alkanes), and other non-polar hydrocarbons known in the art. In some aspects, the C₁-C₁₂ alkane may be heptane or octane.

In operation 140, the prepared precursors may be processed with the assistance of plasma-based systems and methods. The plasma-processing may include providing a carrier gas to transport the selected precursors and to support the existence of the plasma. The plasma may heat the carrier gas and the precursors to induce formation of the solid-state electrolyte materials. For excitation of the plasma, an excitation source may be provided. The plasma excitation source, for example, may be one or more of an AC discharge, a DC discharge, a laser discharge, a radio frequency (RF) source, a microwave (MW) source and/or other energy sources that may induce and/or support the plasma. The plasma may be contained within a plasma flow reactor or other type of plasma system. At least portions of the carrier gas and/or the precursors may be in the actual plasma state (i.e., ionized) whereas other materials may be in a fluidized state in the heated carrier gas.

The carrier gas may be a non-reactive carrier gas, a reactive carrier gas, or a combination thereof, which is supplied at a flow rate suitable to support the movement of the precursor(s) through the plasma-processing and to support the formation of the desired solid-state electrolyte materials. The non-reactive carrier gas may be considered as a carrier gas that does not itself engage in chemical interactions with the precursors during processing. For example, inert gasses such as argon, helium, neon, krypton, xenon, and combinations thereof may be used as non-reactive carrier gasses. In preferred embodiments, the inert gas may be or may comprise argon. A reactive carrier gas may be considered as a carrier gas that does chemically interact with the precursors during the plasma-processing. This may include direct chemical interactions involving the sharing of atomic species or catalytic activity imparted upon the precursors by the gas. In some embodiments, the reactive carrier gas may be one or more of a sulfur containing gas, for example, but not limited to hydrogen sulfide, sulfur vapor, sulfur hexafluoride, and combinations thereof. In another embodiment, the reactive carrier gas may be one or more of an oxygen containing gas, for example, but not limited to water, oxygen, ozone, and combinations thereof. In another embodiment, the reactive carrier gas may be one or more of a nitrogen containing gas, for example, but not limited to ammonia, nitric oxide (NO₂, N₂O₄), and nitrogen gas. In another embodiment, the reactive carrier gas may be one or more of a halogen containing gas, for example, but not limited to chloride gas (Cl₂), bromine gas (Br₂), iodine gas (I₂), hydrogen chloride, hydrogen bromide, and combinations thereof. In other embodiments, the reactive carrier gas may be a hydrocarbon, for example, but not limited to, methane. Carrier gasses may also function to form intermediate compounds during the processing of the precursors into the desired final products. Some gases, such as nitrogen, may be reactive or non-reactive depending on the precursor composition and the plasma-assisted processing conditions. In preferred embodiments, the reactive carrier gas may be or may comprise one or more of ammonia, sulfur, hydrogen sulfide, nitrogen, methane, and combinations thereof.

The carrier gas pressure, flow rate, and species may be varied to adjust precursor heating, reaction kinetics, volume fraction and/or resultant solid-state electrolyte materials particle size.

In some embodiments, the carrier gas may have a flow rate of at least about 0.1 liters per minute per gram of precursors being plasma-processed. In some aspects, the carrier gas may have a flow rate of at least about 0.1, at least 0.2, at least 0.3, at least 0.4, at least 0.5, at least 0.6, at least 0.7, at least 0.8, at least 0.9, at least 1.0, at least 2.0, at least 3.0, at least 4.0, at least 5.0, at least 6.0, at least 7.0, at least 8.0, at least 9.0, or at least 10.0 liters per minute per gram of precursors being plasma-processed.

In additional embodiments, the carrier gas may have a flow rate from about 0 to about 100 liters per minute. In some aspects, the carrier gas may have a flow rate from about 0 liters per minute to about 10 liters per minute, about 0 liters per minute to about 20 liters per minute, about 0 liters per minute to about 30 liters per minute, about 0 liters per minute to about 40 liters per minute, about 0 liters per minute to about 50 liters per minute, about 0 liters per minute to about 60 liters per minute, about 0 liters per minute to about 70 liters per minute, about 0 liters per minute to about 80 liters per minute, about 0 liters per minute to about 90 liters per minute, about 10 liters per minute to about 100 liters per minute, about 20 liters per minute to about 100 liters per minute, about 30 liters per minute to about 100 liters per minute, about 40 liters per minute to about 100 liters per minute, about 50 liters per minute to about 100 liters per minute, about 60 liters per minute to about 100 liters per minute, about 70 liters per minute to about 100 liters per minute, about 80 liters per minute to about 100 liters per minute, about 90 liters per minute to about 100 liters per minute, about 10 liters per minute liters per minute to about 20 liters per minute, about 20 liters per minute to about 30 liters per minute, about 30 liters per minute to about 40 liters per minute, about 40 liters per minute to about 50 liters per minute, about 50 liters per minute to about 60 liters per minute, about 60 liters per minute to about 70 liters per minute, about 70 liters per minute to about 80 liters per minute, about 80 liters per minute to about 90 liters per minute, or about 90 liters per minute to about 100 liters per minute. In some aspects, the carrier gas may have a flow rate of greater than 0 liters per minute. In some additional aspects, the carrier gas may have a flow rate of greater than 100 liters per minute.

In some embodiments, the carrier gas pressure may be from about 1×10⁻⁹ Torr to about 7600 Torr. In some aspects, the carrier gas pressure may be from about 1×10⁻⁹ Torr to about 1×10⁻⁸ Torr, about 1×10⁻⁹ Torr to about 1×10⁻⁷ Torr, about 1×10⁻⁹ Torr to about 1×10⁻⁶ Torr, about 1×10⁻⁹ Torr to about 1×10⁻⁵ Torr, about 1×10⁻⁹ Torr to about 1×10⁻⁴ Torr, about 1×10⁻⁹ Torr to about 1×10⁻³ Torr, about 1×10⁻⁹ Torr to about 1×10⁻² Torr, about 1×10⁻⁹ Torr to about 1×10⁻¹ Torr, about 1×10⁻⁹ Torr to about 1 Torr, about 1×10⁻⁹ Torr to about 10 1×10⁻⁹ Torr, about 1×10⁻⁹ Torr to about 100 Torr, about 1×10⁻⁹ Torr to about 500 Torr, about 1×10⁻⁹ Torr to about 1000 Torr, about 1×10⁻⁹ Torr to about 5000 Torr, about 1×10⁻⁸ Torr to about 7600 Torr, about 1×10⁻⁷ Torr to about 7600 Torr, about 1×10⁻⁶ Torr to about 7600 Torr, about 1×10⁻⁵ Torr to about 7600 Torr, about 1×10⁻⁴ Torr to about 7600 Torr, about 1×10⁻³ Torr to about 7600 Torr, about 1×10⁻² Torr to about 7600 Torr, about 1×10⁻¹ Torr to about 7600 Torr, 1 Torr to about 7600 Torr, about 10 Torr to about 7600 Torr, about 100 Torr to about 7600 Torr, about 500 Torr to about 7600 Torr, about 1000 Torr to about 7600 Torr, about 5000 Torr to about 7600 Torr, about 1 Torr to about 1000 Torr, about 10 Torr to about 1000 Torr, about 100 Torr to about 1000 Torr, about 500 Torr to about 1000 Torr, about 1 Torr to about 500 Torr, about 10 Torr to about 500 Torr, or about 100 Torr to about 500 Torr. In some embodiments, the carrier gas pressure may be greater than 7600 Torr.

Varying the parameters of the carrier and reactive gases changes the fluidization of the precursors and the resultant density of precursors undergoing plasma processing. This, in-turn, alters the thermal dynamics and the processing time and temperature requirements. Proper selection of the reaction temperature and duration of reaction avoids the creation of undesired products and provides for a very fast synthesis. Additionally, many precursor materials and reaction products, especially sulfide materials, may react strongly with metals, such as stainless steel, aluminum, nickel, iron, chrome, etc. that can result in contamination of the products. Processing in a fluidized and/or gaseous state avoids this issue.

Excitation of the plasma may be adjusted to achieve an effective heating temperature from about 70° C. to about 1200° C. As used herein “effective heating temperature” refers to the average temperature of the particles flowing through the plasma, rather than the temperature of the plasma itself. It will be noted that the plasma may have a temperature as high as 4,000 K. In some embodiments, the effective heating temperature may range from about 70° C. to about 100° C., about 70° C. to about 150° C., about 70° C. to about 200° C., about 70° C. to about 250° C., about 70° C. to about 300° C., about 70° C. to about 350° C., about 70° C. to about 400° C., about 70° C. to about 450° C., about 70° C. to about 500° C., about 70° C. to about 550° C., about 70° C. to about 600° C., about 70° C. to about 650° C., about 70° C. to about 600° C., about 70° C. to about 650° C., about 70° C. to about 700° C., about 70° C. to about 750° C., about 70° C. to about 800° C., about 70° C. to about 850° C., about 70° C. to about 900° C., about 70° C. to about 950° C., about 70° C. to about 1000° C., about 70° C. to about 1100° C., about 100° C. to about 1200° C., about 150° C. to about 1200° C., about 200° C. to about 1200° C., about 250° C. to about 1200° C., about 300° C. to about 1200° C., about 350° C. to about 1200° C., about 400° C. to about 1200° C., about 450° C. to about 1200° C., about 500° C. to about 1200° C., about 550° C. to about 1200° C., about 600° C. to about 1200° C., about 650° C. to about 1200° C., about 700° C. to about 1200° C., about 750° C. to about 1200° C., about 800° C. to about 1200° C., about 850° C. to about 1200° C., about 900° C. to about 1200° C., about 950° C. to about 1200° C., about 1000° C. to about 1200° C., about 1100° C. to about 1200° C., about 100° C. to about 1100° C., about 200° C. to about 1000° C., about 300° C. to about 900° C., about 400° C. to about 800° C., or about 500° C. to about 700° C. In some embodiments, the effective heating temperature may be greater than about 70° C. In some embodiments, the effective heating temperature may be greater than 1200° C. In some embodiments, excitation of the plasma may be adjusted to achieve an effective heating temperature from about 70° C. to about 1500° C., about 1000° C. to about 2000° C., about 70° C. to about 2000° C., about 2000° C. to about 3000° C., about 70° C. to about 3000° C., about 3000° C. to about 4000° C., about 70° C. to about 4000° C., about 4000° C. to about 5000° C., or about 70° C. to about 5000° C. In some embodiments, the effective heating temperature may be greater than about 5000° C. It will be appreciated by those having ordinary skill in the art that different materials may be heated to different effective heating temperatures during the plasma processing based on factors including the heat capacity of the material, thermal conductivity of the material, flow rate of the material through the plasma, particle size of the material etc.

The heating may specifically reach a crystallization temperature of a desired solid-state electrolyte material and maintain that temperature for a period of, for example, greater than about 1 microsecond to about 60 seconds to support formation of the desired material. In some aspects, the crystallization temperature may be maintained for a fast reaction period from about 1 microsecond to about 10 microseconds, about 1 microsecond to about 100 microseconds, about 1 microsecond to about 1 millisecond, about 1 microsecond to about 10 milliseconds, about 1 microsecond to about 100 milliseconds, about 1 microsecond to about 1 second, about 1 microsecond to about 10 seconds, about 1 microsecond to about 30 seconds, about 10 microseconds to about 60 seconds, about 100 microseconds to about 60 seconds, about 1 millisecond to about 60 seconds, about 10 milliseconds to about 60 seconds, about 100 milliseconds to about 60 seconds, about 1 second to about 60 seconds, about 10 seconds to about 60 seconds, about 30 seconds to about 60 seconds. In some aspects, the crystallization temperature may be maintained for a fast reaction period from about 10 microseconds to about 1 seconds, about 100 microseconds to about 1 second, about 1 millisecond to about 1 second, about 10 milliseconds to about 1 second, about 100 milliseconds to about 1 second, about 10 microseconds to about 100 milliseconds, about 10 microseconds to about 10 milliseconds, about 10 microseconds to about 1 millisecond, or about 10 microseconds to about 100 microseconds. In some preferred embodiments, the crystallization temperature may be maintained for a period from about 10 milliseconds to about 3 seconds, or more preferably from about 100 milliseconds to about 2 seconds, or even more preferably from about 100 milliseconds to about 1 second.

In some embodiments, the resultant solid-state electrolyte materials may have a particle size from about 1 nm to about 10 mm. In some aspects, the resultant solid-state electrolyte materials may have a particle size from about 1 nm to about 50 nm, about 1 nm to about 100 nm, about 1 nm to about 250 nm, about 1 nm to about 500 nm, about 1 nm to about 750 nm, about 1 nm to about 1 μm about 1 nm to about 10 μm, about 1 nm to about 50 μm, about 1 nm to about 100 μm, about 1 nm to about 250 μm, about 1 nm to about 500 μm, about 1 nm to about 750 μm, about 1 nm to about 1 mm, about 1 nm to about 5 mm, or about 1 nm to about 10 mm. In a particular embodiment, the resultant solid-state electrolyte materials have a particle size of about 1 μm to about 5 μm, preferably about 3 μm.

Resultant solid-state electrolyte materials may be further processed in step 150 and, for example, incorporated into electrochemical cells. In some embodiments, step 150 may include reducing the particle size of the solid-state electrolyte materials such as by milling, grinding, high shear mixing, thermal treating and other methods. In some embodiments, step 150 may include washing the solid-state electrolyte materials. In still further embodiments, step 150 may include coating the solid-state electrolyte materials.

In some embodiments, the resultant solid-state electrolyte materials may have a purity of about 30% by weight or greater. In some aspects, the resultant solid-state electrolyte materials may have a purity of about 30% to about 40%, about 30% to about 50%, about 30% to about 60%, about 30% to about 70%, about 30% to about 80%, about 30% to about 90%, about 30% to about 95%, about 30% to about 99%, about 30% to about 99.9%, about 40% to about 99.9%, about 50% to about 99.9%, about 60% to about 99.9%, about 70% to about 99.9%, about 80% to about 99.9%, about 90% to about 99.9%, about 40% to about 50%, about 50% to about 60%, about 60% to about 70%, about 70% to about 80%, about 80% to about 90%, about 90% to about 95%, or about 95% to about 99.9% by weight. In some exemplary embodiments, the solid-state electrolyte materials may have a purity of greater than about 80% by weight, greater than about 90% by weight, greater than about 95% by weight, greater than about 99% by weight, or greater than about 99.9% by weight.

In some embodiments, the solid-state electrolyte materials made by the process 100 may include lithium rich anti-perovskite (LiRAP) materials. The LiRAP materials may include, but are not limited to Li₃OCl, Li₃OBr, Li₃OI, Li₃SCl, Li₃SBr, Li₃SI, and their solid solutions.

In some embodiments, the solid-state electrolyte materials made by the process 100 may include sulfide electrolyte materials, such as but not limited to lithium-boron-sulfur (LBS) materials. In some aspects, the LBS materials may include, but are not limited to Li₃BS₃, Li₂B₂S₅, Li₅B₇S₁₃, and Li₉B₁₉S₃₃.

In additional embodiments, the solid-state electrolyte materials made by the process 100 may include sulfide electrolyte materials that contain phosphorus and/or a halogen (LPSX Materials). In some aspects, the LPSX materials may include, but are not limited to Li₆PS₅Cl, Li₆PS₅Br, Li₆PS₅Cl_{0.5}Br_{0.5}, Li₇P₂S₈Cl, Li₇P₂S₈Br, Li₇P₂S₈I, Li₇P₂S₈Cl_{0.5}Br_{0.5}, Li_{7-a-b}PS_{6-(a+b)}XₐY_{b} or Li₇P₂S₈XₐY_{b}, where X and Y includes a halogen, such as F, Cl, Br, or I or pseudohalogens, such as BH₄, BF₄, OCN, CN, SCN, SH, NO, or NO₂ where 0≤a≤2 and 0≤b≤2.

In some embodiments, the reaction for producing the desired solid-state electrolyte material may include, but is not limited to the following:

Li₂S—P₂S₅—LiX

where X includes a halogen, such as F, C, Br, or I or pseudohalogens, such as BH₄, BF₄, OCN, CN, SCN, SH, NO, or NO₂.

Li₂S+P₂S₅+LiX+LiY→Li_{7-a-b}PS_{6-(a+b)}XₐY_{b}

where X and Y includes a halogen, such as F, C, Br, or I or pseudohalogens, such as BH₄, BF₄, OCN, CN, SCN, SH, NO, or NO₂ where 0≤a≤2 and 0≤b≤2.

5Li₂S+P₂S₅+2LiCl→2Li₆PS₅Cl

5Li₂S+P₂S₅+2LiBr→2Li₆PS₅Br

5Li₂S+P₂S₅+LiCl+LiBr→2Li₆PS₅Cl_{0.5}Br_{0.5}

Li₂S+P₂S₅+LiX+LiY→Li₇P₂S₈XₐY_{b}

where X and Y includes a halogen, such as F, C, Br, or I or pseudohalogens, such as BH₄, BF₄, OCN, CN, SCN, SH, NO, or NO₂.

3Li₂S+P₂S₅+LiCl→Li₇P₂S₈Cl

3Li₂S+P₂S₅+LiBr→Li₇P₂S₈Br

3Li₂S+P₂S₅+LiI→Li₇P₂S₈I

3Li₂S+P₂S₅+LiBr+LiCl→Li₇P₂S₈Cl_{0.5}Br_{0.5}

Li₂S—B₂S₃

3Li₂S+B₂S₃→Li₃BS₃

Li₂S+B₂S₃+S→Li₂B₂S₅

5Li₂S+7B₂S₃→2Li₅B₇S₁₃

5Li₂S+5B₂S₃→Li₁₀B₁₀S₂₀

9Li₂S+19B₂S₃→2Li₉B₁₉S₃₃

LiCl+Li₂O→Li₃OCl

LiCl+2LiOH→Li₃OCl+H₂O

Other acceptable materials include Li₂S—P₃N₅, Li₂S—P₃N₅—P₂S₅, Li₂S—P₃N₅—P₂S₅—LiX, Li₂S—Li₃N—P₂S₅—LiX, or Li₂S—Li₃N—P₂S₅. Any of the chemical reactions described herein may be produced in a solvent free manner and/or in a fast reaction period of time.

FIG. 3B is a flow chart of a process for plasma-assisted synthesis of precursors for synthesizing solid-state electrolyte materials. Process 300 may begin with preparation step 210 wherein any preparation action, such as purification, and equipment preparation may take place. It should be recognized that some preprocessing may also occur in a separate process from the plasma-process and such processed materials used in the method. It will also be understood that the preparation step 110 of process 100 in FIG. 1 may include process 300, i.e., synthesis of precursor materials.

After the initial preparation 310, process 300 involves operation 320 where one or more reactants may be provided in amounts by weight and/or molar volume. Reactants for precursor synthesis may include lithium containing reactants, phosphorus containing reactants, sulfur containing reactants, and other reactants for making precursors.

In some embodiments, the lithium containing reactants may include but are not limited to Li₂SO₄, LiOH, Li₂O, Li₂CO₃, LiNO₃, Li₃N, LiX, and LiY where X and Y include halogens, such as F, Cl, Br, or I, and pseudohalogens, such as BH₄, BF₄, OCN, CN, SCN, SH, NO, or NO₂. In some additional embodiments, the lithium containing reactants may include LiX₍₁₋ₐ₎Yₐ, wherein the X and Y include halogens, such as F, C, Br, or I, and/or pseudohalogens, such as BH₄, BF₄, OCN, CN, SCN, SH, NO, or NO₂ where 0≤a≤1

In some embodiments, the phosphorus containing reactants may include but are not limited to P₂S₅, P₂O₅, and elemental phosphorus.

In some embodiments, the sulfur containing reactants may include but are not limited to H₂S and elemental sulfur.

In some embodiments, the other reactants may include carbon, ammonium, and elemental boron.

In operation 330, the reactants may be prepared for plasma processing by way of mixing, alloying, solution processing, and by various particle-size reduction techniques, alone or in various possible combinations, including milling, grinding, high shear mixing, thermal treating, and other methods to reduce the particle size of the precursors. Reactant particle size may include a range from 1 nm to 10 mm. Smaller particle sizes are preferred, as smaller particle sizes allow for better control of the ratio of reactants entering the plasma chamber. The particle size of at least one of the reactants may be reduced prior to plasma-processing. In some embodiments, the particle size of all of the reactants may be reduced prior to plasma processing. In some embodiments, operation 330 is performed without any chemical reactions occurring. In other embodiments, some chemical reactions may occur in operation 330.

In some embodiments, after particle-size reduction, the reactants may have a particle size from about 1 nm to about 10 mm. In some aspects, the reactants may have a particle size from about 1 nm to about 50 nm, about 1 nm to about 100 nm, about 1 nm to about 250 nm, about 1 nm to about 500 nm, about 1 nm to about 750 nm, about 1 nm to about 1 μm about 1 nm to about 10 μm, about 1 nm to about 50 μm, about 1 nm to about 100 μm, about 1 nm to about 250 μm, about 1 nm to about 500 μm, about 1 nm to about 750 μm, about 1 nm to about 1 mm, about 1 nm to about 5 mm, or about 1 nm to about 10 mm.

In some embodiments, all of the reactants may have a uniform particle size. In other embodiments, one or more reactants may have a larger or smaller particle size as compared to the other reactants. Varying the particle size of the reactants may be advantageous when the reactants have substantially different melting points and/or boiling points. For example, a reactant particle with a low melting point and boiling point may substantially or completely evaporate before reacting with the remaining reactants if the particle size of the reactants is small. Thus, the particle size of the reactants may be modified to increase reaction yields.

In some embodiments, the processing in operation 330 may occur in a solvent-free environment; i.e., the mixing, alloying, milling, grinding, high shear mixing, thermal treating, or other methods to reduce the particle size of the precursors is performed in the absence of a solvent. This results not only in a solvent-free process, but also ensures that the end product is free of any solvent as well.

In other embodiments, the processing in operation 330 occurs in the presence of a solvent. In some aspects, the solvent may be an aprotic solvent. In some aspects, the solvent may be a protic solvent. In some particular aspects, the solvent may be a non-polar hydrocarbon, including but not limited to benzene, toluene, xylenes, C₁-C₁₂ alkanes, and other non-polar hydrocarbons known in the art. In some aspects, the C₁-C₁₂ alkane may be heptane or octane.

In operation 340, the prepared reactants may be processed with the assistance of plasma-based systems and methods. The plasma-processing may include providing a carrier gas to transport the selected reactants and to support the existence of the plasma. The plasma may heat the carrier gas and the reactants to induce formation of the precursors. For excitation of the plasma, an excitation source may be provided. The plasma excitation source, for example, may be one or more of an AC discharge, a DC discharge, a laser discharge, a radio frequency (RF) source, a microwave (MW) source and/or other energy sources that may induce and/or support the plasma. The plasma may be contained within a plasma flow reactor or other type of plasma system. At least portions of the carrier gas and/or the precursors may be in the actual plasma state (i.e., ionized) whereas other materials may be in a fluidized state in the heated carrier gas.

The carrier gas may be a non-reactive carrier gas or a reactive carrier gas, which is supplied at a flow rate suitable to support the movement of the reactants through the plasma-processing and to support the formation of the desired solid-state electrolyte materials. The non-reactive carrier gas may be considered as a carrier gas that does not itself engage in chemical interactions with the reactants during processing. For example, inert gasses such as argon and helium may be used as non-reactive carrier gasses. In preferred embodiments, the inert gas may be argon. A reactive carrier gas may be considered as a carrier gas that does chemically interact with the reactants during the plasma-processing. This may include direct chemical interactions involving the sharing of atomic species or catalytic activity imparted upon the precursors by the gas. In some embodiments, the reactive carrier gas may be one or more of a sulfur containing gas, for example, but not limited to hydrogen sulfide, sulfur vapor, sulfur hexafluoride. In another embodiment, the reactive carrier gas may be one or more of an oxygen containing gas, for example, but not limited to water, oxygen, and ozone. In another embodiment, the reactive carrier gas may be one or more of a nitrogen containing gas, for example, but not limited to ammonia, nitric oxide (NO₂, N₂O₄), and nitrogen gas. In another embodiment, the reactive carrier gas may be one or more of a halogen containing gas, for example, but not limited to chloride gas (Cl₂), bromine gas (Br₂), iodine gas (I₂), hydrogen fluoride, hydrogen chloride, or hydrogen bromide. In other embodiments, the reactive carrier gas may be a hydrocarbon, for example, but not limited to, methane. In another embodiment, the reactive carrier gas may a phosphorus-containing gas or a boron-containing gas. Carrier gasses may also function to form intermediate compounds during the processing of the precursors into the desired final products. Some gases, such as nitrogen, may be reactive or non-reactive depending on the precursor composition and the plasma-assisted processing conditions. In preferred embodiments, the reactive carrier gas may be one or more of ammonia, sulfur, hydrogen sulfide, nitrogen, and methane.

The carrier gas pressure, flow rate, and species may be varied to adjust precursor heating, reaction kinetics, volume fraction and/or resultant solid-state electrolyte materials particle size.

In some embodiments, the carrier gas may have a flow rate of at least about 0.1 liters per minute per gram of reactants being processed. In some aspects, the carrier gas may have a flow rate of at least about 0.1, at least 0.2, at least 0.3, at least 0.4, at least 0.5, at least 0.6, at least 0.7, at least 0.8, at least 0.9, at least 1.0, at least 2.0, at least 3.0, at least 4.0, at least 5.0, at least 6.0, at least 7.0, at least 8.0, at least 9.0, or at least 10.0 liters per minute per gram of reactants being plasma-processed.

In additional embodiments, the carrier gas may have a flow rate from about 0 to about 100 liters per minute. In some aspects, the carrier gas may have a flow rate from about 0 liters per minute to about 10 liters per minute, about 0 liters per minute to about 20 liters per minute, about 0 liters per minute to about 30 liters per minute, about 0 liters per minute to about 40 liters per minute, about 0 liters per minute to about 50 liters per minute, about 0 liters per minute to about 60 liters per minute, about 0 liters per minute to about 70 liters per minute, about 0 liters per minute to about 80 liters per minute, about 0 liters per minute to about 90 liters per minute, about 10 liters per minute to about 100 liters per minute, about 20 liters per minute to about 100 liters per minute, about 30 liters per minute to about 100 liters per minute, about 40 liters per minute to about 100 liters per minute, about 50 liters per minute to about 100 liters per minute, about 60 liters per minute to about 100 liters per minute, about 70 liters per minute to about 100 liters per minute, about 80 liters per minute to about 100 liters per minute, about 90 liters per minute to about 100 liters per minute, about 10 liters per minute liters per minute to about 20 liters per minute, about 20 liters per minute to about 30 liters per minute, about 30 liters per minute to about 40 liters per minute, about 40 liters per minute to about 50 liters per minute, about 50 liters per minute to about 60 liters per minute, about 60 liters per minute to about 70 liters per minute, about 70 liters per minute to about 80 liters per minute, about 80 liters per minute to about 90 liters per minute, or about 90 liters per minute to about 100 liters per minute. In some aspects, the carrier gas may have a flow rate of greater than 0 liters per minute. In some additional aspects, the carrier gas may have a flow rate of greater than 100 liters per minute.

In some embodiments, the carrier gas pressure may be from about 1×10⁻⁹ Torr to 7600 Torr. In some aspects, the carrier gas pressure may range from about 1×10⁻⁹ Torr to about 1×10⁻⁸ Torr, about 1×10⁻⁹ Torr to about 1×10⁻⁷ Torr, about 1×10⁻⁹ Torr to about 1×10⁻⁶ Torr, about 1×10⁻⁹ Torr to about 1×10⁻⁵ Torr, about 1×10⁻⁹ Torr to about 1×10⁻⁴ Torr, about 1×10⁻⁹ Torr to about 1×10⁻³ Torr, about 1×10⁻⁹ Torr to about 1×10⁻² Torr, about 1×10⁻⁹ Torr to about 1×10⁻¹ Torr, about 1×10⁻⁹ Torr to about 1 Torr, about 1×10⁻⁹ Torr to about 10 1×10⁻⁹ Torr, about 1×10⁻⁹ Torr to about 100 Torr, about 1×10⁻⁹ Torr to about 500 Torr, about 1×10⁻⁹ Torr to about 1000 Torr, about 1×10⁻⁹ Torr to about 5000 Torr, about 1×10⁻⁸ Torr to about 7600 Torr, about 1×10⁻⁷ Torr to about 7600 Torr, about 1×10⁻⁶ Torr to about 7600 Torr, about 1×10⁻⁵ Torr to about 7600 Torr, about 1×10⁻⁴ Torr to about 7600 Torr, about 1×10⁻³ Torr to about 7600 Torr, about 1×10⁻² Torr to about 7600 Torr, about 1×10⁻¹ Torr to about 7600 Torr, 1 Torr to about 7600 Torr, about 10 Torr to about 7600 Torr, about 100 Torr to about 7600 Torr, about 500 Torr to about 7600 Torr, about 1000 Torr to about 7600 Torr, about 5000 Torr to about 7600 Torr, about 1 Torr to about 1000 Torr, about 10 Torr to about 1000 Torr, about 100 Torr to about 1000 Torr, about 500 Torr to about 1000 Torr, about 1 Torr to about 500 Torr, about 10 Torr to about 500 Torr, or about 100 Torr to about 500 Torr.

Varying the parameters of the carrier and reactive gases changes the fluidization of the reactants and the resultant density of reactants undergoing plasma processing. This, in-turn, alters the thermal dynamics and the processing time and temperature requirements. Proper selection of the reaction temperature and duration of reaction avoids the creation of undesired products and provides for a very fast synthesis. Additionally, many reactants materials and reaction products, especially sulfide materials, may react strongly with metals, such as stainless steel, aluminum, nickel, iron, chrome, etc. that can result in contamination of the products. Processing in a fluidized and/or gaseous state avoids this issue.

Excitation of the plasma may be adjusted to achieve an effective heating temperature from about 70° C. to about 1200° C. In some embodiments, the effective heating temperature may range from about 70° C. to about 100° C., about 70° C. to about 150° C., about 70° C. to about 200° C., about 70° C. to about 250° C., about 70° C. to about 300° C., about 70° C. to about 350° C., about 70° C. to about 400° C., about 70° C. to about 450° C., about 70° C. to about 500° C., about 70° C. to about 550° C., about 70° C. to about 600° C., about 70° C. to about 650° C., about 70° C. to about 600° C., about 70° C. to about 650° C., about 70° C. to about 700° C., about 70° C. to about 750° C., about 70° C. to about 800° C., about 70° C. to about 850° C., about 70° C. to about 900° C., about 70° C. to about 950° C., about 70° C. to about 1000° C., about 70° C. to about 1100° C., about 100° C. to about 1200° C., about 150° C. to about 1200° C., about 200° C. to about 1200° C., about 250° C. to about 1200° C., about 300° C. to about 1200° C., about 350° C. to about 1200° C., about 400° C. to about 1200° C., about 450° C. to about 1200° C., about 500° C. to about 1200° C., about 550° C. to about 1200° C., about 600° C. to about 1200° C., about 650° C. to about 1200° C., about 700° C. to about 1200° C., about 750° C. to about 1200° C., about 800° C. to about 1200° C., about 850° C. to about 1200° C., about 900° C. to about 1200° C., about 950° C. to about 1200° C., about 1000° C. to about 1200° C., about 1100° C. to about 1200° C., about 100° C. to about 1100° C., about 200° C. to about 1000° C., about 300° C. to about 900° C., about 400° C. to about 800° C., or about 500° C. to about 700° C. In some embodiments, the effective heating temperature may be greater than about 70° C. In some embodiments, the effective heating temperature may be greater than about 1200° C. In some embodiments, excitation of the plasma may be adjusted to achieve an effective heating temperature from about 70° C. to about 1500° C., about 1000° C. to about 2000° C., about 70° C. to about 2000° C., about 2000° C. to about 3000° C., about 70° C. to about 3000° C., about 3000° C. to about 4000° C., about 70° C. to about 4000° C., about 4000° C. to about 5000° C., or about 70° C. to about 5000° C. In some embodiments, the effective heating temperature may be greater than about 5000° C. It will be appreciated by those having ordinary skill in the art that different materials may be heated to different effective heating temperatures during the plasma processing based on factors including the heat capacity of the material, thermal conductivity of the material, flow rate of the material through the plasma, particle size of the material, etc.

The heating may specifically reach a crystallization temperature of a desired precursor and maintain that temperature for a fast reaction period of, for example, greater than about 1 microsecond to about 60 seconds to support formation of the desired precursor. In some aspects, the crystallization temperature may be maintained for a period from about 1 microsecond to about 10 microseconds, about 1 microsecond to about 100 microseconds, about 1 microsecond to about 1 millisecond, about 1 microsecond to about 10 milliseconds, about 1 microsecond to about 100 milliseconds, about 1 microsecond to about 1 second, about 1 microsecond to about 10 seconds, about 1 microsecond to about 30 seconds, about 10 microseconds to about 60 seconds, about 100 microseconds to about 60 seconds, about 1 millisecond to about 60 seconds, about 10 milliseconds to about 60 seconds, about 100 milliseconds to about 60 seconds, about 1 second to about 60 seconds, about 10 seconds to about 60 seconds, about 30 seconds to about 60 seconds. In some aspects, the crystallization temperature may be maintained for a period from about 10 microseconds to about 1 seconds, about 100 microseconds to about 1 second, about 1 millisecond to about 1 second, about 10 milliseconds to about 1 second, about 100 milliseconds to about 1 second, about 10 microseconds to about 100 milliseconds, about 10 microseconds to about 10 milliseconds, about 10 microseconds to about 1 millisecond, or about 10 microseconds to about 100 microseconds.

In some embodiments, the resultant precursors may have a particle size from about 1 nm to about 10 mm. In some aspects, the resultant precursors may have a particle size from about 1 nm to about 50 nm, about 1 nm to about 100 nm, about 1 nm to about 250 nm, about 1 nm to about 500 nm, about 1 nm to about 750 nm, about 1 nm to about 1 μm about 1 nm to about 10 μm, about 1 nm to about 50 μm, about 1 nm to about 100 μm, about 1 nm to about 250 μm, about 1 nm to about 500 μm, about 1 nm to about 750 μm, about 1 nm to about 1 mm, about 1 nm to about 5 mm, or about 1 nm to about 10 mm.

Resultant precursors may be further processed in step 350 and, for example, further plasma processed into solid-state electrolyte materials. In some embodiments, step 350 may include reducing the particle size of the solid-state electrolyte materials such as by milling, grinding, high shear mixing, thermal treating and other methods. In some embodiments, step 350 may include washing the solid-state electrolyte materials. In still further embodiments, step 350 may include coating the solid-state electrolyte materials.

In some embodiments, the resultant precursors may have a purity of about 30% by weight or greater. In some aspects, the resultant precursors may have a purity of about 30% to about 40%, about 30% to about 50%, about 30% to about 60%, about 30% to about 70%, about 30% to about 80%, about 30% to about 90%, about 30% to about 95%, about 30% to about 99%, about 30% to about 99.9%, about 40% to about 99.9%, about 50% to about 99.9%, about 60% to about 99.9%, about 70% to about 99.9%, about 80% to about 99.9%, about 90% to about 99.9%, about 40% to about 50%, about 50% to about 60%, about 60% to about 70%, about 70% to about 80%, about 80% to about 90%, about 90% to about 95%, or about 95% to about 99.9% by weight. In some exemplary embodiments, the precursors may have a purity of greater than about 80% by weight, greater than about 90% by weight, greater than about 95% by weight, greater than about 97% by weight, greater than about 98% by weight, greater than about 99% by weight, or greater than about 99.9% by weight.

In some embodiments, the precursors made by the process 300 may include Li₂S, P₃N₅, B₂S₃, Li₃N, SiS₂, GeS, or LiX₍₁₋ₐ₎Yₐ, where X and Y include halogens, such as F, Cl, Br, or I, and pseudohalogens, such as BH₄, BF₄, OCN, CN, SCN, SH, NO, or NO₂ where 0≤a≤1.

In some embodiments, the reactants may produce the desired precursor as well as a byproduct. The byproducts from these reactions may include, but are not limited to, CO, CO₂, H₂O, H₂S, O₂, N₂, NOₓ, S, SO, SO₂, and CS₂. Those having ordinary skill in the art will appreciate that the byproducts produced will depend on the reactants included in the synthesis. In some aspects, the process 300 may include separating the byproducts from the precursor. The separating may be accomplished by separation methods known to those having skill in the art. In some aspects, the separating may be accomplished by venting gaseous byproducts to a ventilation hood or to a scrubber.

In some embodiments, the reaction for producing the desired precursor may include, but is not limited to the following:

Li₂SO₄+4C→Li₂S+4CO

2LiOH+H₂S→2Li₂S+2H₂O

3P₂S₅+10NH₃→P₃N₅+15H₂S

2B+3S→B₂S₃

3LiOH+NH₃→Li₃N+3H₂O

LiX+LiY→LiX₍₁₋ₐ₎Yₐ

where X and Y include halogens, such as F, Cl, Br, or I, and pseudohalogens, such as BH₄, BF₄, OCN, CN, SCN, SH, NO, or NO₂ where 0≤a≤1. The plasma in the previous examples can be reactive or non-reactive. Any of the chemical reactions described herein may be produced in a solvent free manner.

When a reactive carrier gas or plasma is used, the reactions may resemble the following where (RCG/P=Reactive Carrier Gas or Plasma):

2LiOH+H₂S(RCG/P)→Li₂S+2H₂O→Li₂S+P₂S₅+LiX

Li₂CO₃+H₂S(RCG/P)→Li₂S+H₂O+CO₂→Li₂S+P₂S₅+LiX

In these exemplary reactions, the plasma may heat the materials to the reaction temperature, and/or the reactive carrier gas H₂S may be ionized to form a plasma, which then reacts with the reactant(s).

The H₂O and/or CO₂ can be removed before introducing the remaining materials allowing for a water-and oxide-free solid electrolyte material. As used herein, a “water-free solid electrolyte material” refers to a material that includes less than 10 wt % water, including less than 9 wt % water, less than 8 wt % water, less than 7 wt % water, less than 6 wt % water, less than 5 wt % water, less than 4 wt % water, less than 3 wt % water, less than 2 wt % water, less than 1 wt % water, less than 0.5 wt % water, less than 0.1 wt % water, less than 0.01 wt % water, and less than 0.001 wt % water. As used herein, an “oxide-free solid electrolyte material” refers to a material that includes less than 10 wt % oxide, including less than 9 wt % oxide, less than 8 wt % oxide, less than 7 wt % oxide, less than 6 wt % oxide, less than 5 wt % oxide, less than 4 wt % oxide, less than 3 wt % oxide, less than 2 wt % oxide, less than 1 wt % oxide, less than 0.5 wt % oxide, less than 0.1 wt % oxide, less than 0.01 wt % oxide, and less than 0.001 wt % oxide.

When the carrier gas is NH₃, the reaction may be:

3P₂S₅+10NH₃(RCG/P)→2P₃N₅+15H₂S

3LiOH+NH₃(RCG/P)→Li₃N+3H₂O

The H₂S and the H₂O can be removed from the above reactions, leaving the final resultant materials to react according to:

P₂S₅+NH₃(RCG/P)→P₃N₅+H₂S→P₃N₅+LiOH+NH₃(RCG/P)→P₃N₅+Li₃N+H₂O+P₃N₅+Li₃N

In some examples, a new carrier gas may be generated during the plasma-processing. A non-limiting example of generating a new carrier gas during the plasma process is:

3P₂S₅+10NH₃(RCG/P)→2P₃N₅+15H₂S

The NH₃ is consumed in the reaction generating a new carrier gas, H₂S. The newly generated H₂S may be used to convert LiOH into Li₂S using the mechanism below:

2LiOH+H₂S→Li₂S+2H₂O

The newly generated H₂O may be removed from the system and the products from the two reactions may be passed though plasma to react according to:

3P₂S₅+10NH₃(RCG/P)→2P₃N₅+15H₂S+LiOH→P₃N₅+H₂S+Li₂S+H₂O→Li₂S+P₃N₅

The term “battery” in the art and herein can be used in various ways and may refer to an individual cell having an anode and cathode separated by an electrolyte, which may be a solid electrolyte, as well as a collection of such cells connected in various arrangements. A solid-state electrolyte cell may include more than one anode and cathode, separated by solid electrolyte layers, and may be encased within a flexible “pouch” that accommodates the expansion and contraction of the anode and cathode as the cell charges and discharges. Although many examples are discussed herein as applicable to a battery or a discrete cell, it should be appreciated that the systems and methods described may apply to many different types of batteries, battery chemistries, and may range from an individual cell to batteries involving different possible interconnections of cells such as cells coupled in parallel, series, and parallel and series. Generally speaking, the plasma system described herein may be used to produce material used in battery cells. For example, the plasma system may produce solid electrolyte material used in producing a battery, which may be solid-state batteries.

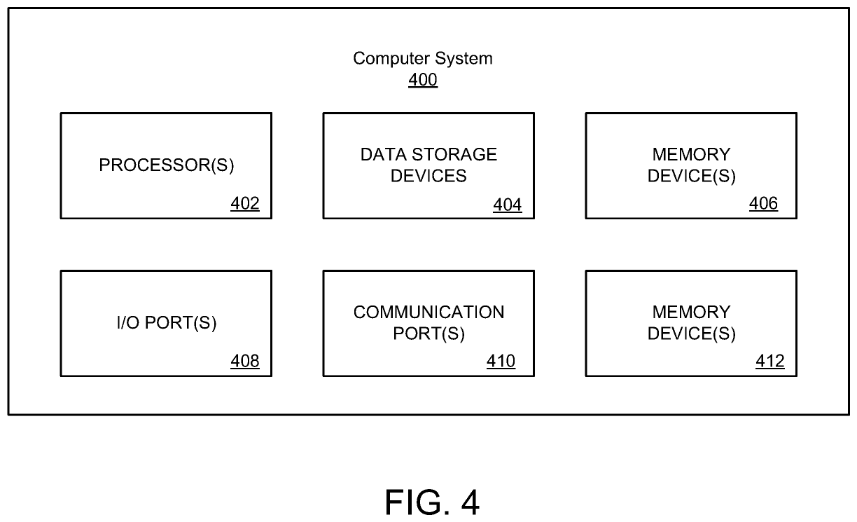

Referring to FIG. 4, a detailed description of an example computing system 400 having one or more computing units that may implement various systems and methods discussed herein is provided. For example, the system may control the power source to ignite and maintain the plasma. The system may control carries gas pressure and flow rates, control electrode positioning when such are movably mounted, and control and/or monitor other features of the system. The computing system 400 may be part of a controller, may be in operable communication with various implementation discussed herein, may run various operations related to the method or methods discussed herein, may run offline to process various data, and may be part of overall systems discussed herein. The computing system 400 may process various signals discussed herein and/or may provide various signals discussed herein. For example, the system may receive and process sensor data from the plasma system and control various aspects of the system responsive to the same, including temperature sensors, pressure and flow rate sensors, valve position sensors, and other sensors. It will be appreciated that specific implementations of these devices may be of differing possible specific computing architectures, not all of which are specifically discussed herein but will be understood by those of ordinary skill in the art. In such various possible implementations, more or fewer components discussed below may be included, interconnections and other changes made, as will be understood by those of ordinary skill in the art.

The computer system 400 may be a computing system that is capable of executing a computer program product to execute a computer process. Data and program files may be input to the computer system 400, which reads the files and executes the programs therein. Some of the elements of the computer system 400 are shown in FIG. 4, including one or more hardware processors 402, one or more data storage devices 404, one or more memory devices 406, and/or one or more ports 408-412. Additionally, other elements that will be recognized by those skilled in the art may be included in the computing system 400 but are not explicitly depicted in FIG. 4 or discussed further herein. Various elements of the computer system 400 may communicate with one another by way of one or more communication buses, point-to-point communication paths, or other communication means not explicitly depicted in FIG. 4. Similarly, in various implementations, various elements disclosed in the system may or not be included in any given implementation.

The processor 402 may include, for example, a central processing unit (CPU), a microprocessor, a microcontroller, a digital signal processor (DSP), field programmable gate array (FPGA), application specific integrated circuit (ASIC), and/or combinations of the same, and/or one or more internal levels of cache. There may be one or more processors 402, such that the processor 402 comprises a single processing unit, or a plurality of processing units capable of executing different sets of instructions and/or performing operations in parallel with each other, commonly referred to as a parallel processing environment.

The presently described technology in various possible combinations may be implemented, at least in part, in software stored on the data stored device(s) 404, stored on the memory device(s) 406, and/or communicated via one or more of the ports 408-412, thereby transforming the computer system 400 in FIG. 4 to a special purpose machine, which may be involved in implementing the operations described herein.

The one or more data storage devices 404 may include any non-volatile data storage device capable of storing data generated or employed within the computing system 400, such as computer executable instructions for performing a computer process, which may include instructions of both application programs and an operating system (OS) that manages the various components of the computing system 400. The data storage devices 404 may include, without limitation, magnetic disk drives, optical disk drives, solid state drives (SSDs), flash drives, and the like. The data storage devices 404 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 406 may include volatile memory (e.g., dynamic random-access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 404 and/or the memory devices 406, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 400 includes one or more ports, such as an input/output (I/O) port 408, a communication port 410, and a sub-systems port 412, for communicating with other computing, network, or vehicle devices. It will be appreciated that the ports 408-412 may be combined or separate and that more or fewer ports may be included in the computer system 400. The I/O port 408 may be connected to an I/O device, or other device, by which information is input to or output from the computing system 400. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 400 via the I/O port 408. In some examples, such inputs may be distinct from the various system and method discussed with regard to the preceding figures. Similarly, the output devices may convert electrical signals received from computing system 400 via the I/O port 408 into signals that may be sensed or used by the various methods and system discussed herein. The input device may be an alphanumeric input device, including alphanumeric and other keys for communicating information and/or command selections to the processor 402 via the I/O port 408.

The environment transducer devices convert one form of energy or signal into another for input into or output from the computing system 400 via the I/O port 408. For example, an electrical signal generated within the computing system 400 may be converted to another type of signal, and/or vice-versa. In one implementation, the environment transducer devices sense characteristics or aspects of an environment local to or remote from the computing device 400, such as temperature, pressure, magnetic field, electric field, voltage and currents of the electrodes or other parts of the system, chemical properties, and/or the like.

In one implementation, a communication port 410 may be connected to a network by way of which the computer system 400 may receive network data useful in executing the methods and systems set out herein as well as transmitting information and network configuration changes determined thereby. For example, charging protocols may be updated, battery measurement or calculation data shared with external system, and the like. The communication port 410 connects the computer system 400 to one or more communication interface devices configured to transmit and/or receive information between the computing system 400 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 410 to communicate with one or more other machines, either directly over a point-to-point communication path, over a wide area network (WAN) (e.g., the Internet), over a local area network (LAN), over a cellular (e.g., third generation (3G), fourth generation (4G), or fifth generation (5G)) network), or over another communication means.

The computer system 400 may include a sub-systems port 412 for communicating with one or more systems related to a device being charged according to the methods and system described herein to control an operation of the same and/or exchange information between the computer system 400 and one or more sub-systems of the device.

The system set forth in FIG. 4 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various operations, which also may be referred to as steps, which are described in this specification. The operations may be performed by hardware components or may be embodied in machine-executable instructions, which may be used to cause a general-purpose or special-purpose processor programmed with the instructions to perform the operations. Alternatively, the operations may be performed by a combination of hardware, software and/or firmware.

Although various representative embodiments of this invention have been described above with a certain degree of particularity, those skilled in the art could make numerous alterations to the disclosed embodiments without departing from the spirit or scope of the inventive subject matter set forth in the specification. All directional references (e.g., upper, lower, upward, downward, left, right, leftward, rightward, top, bottom, above, below, vertical, horizontal, clockwise, and counterclockwise) are only used for identification purposes to aid the reader's understanding of the embodiments of the present invention, and do not create limitations, particularly as to the position, orientation, or use of the invention unless specifically set forth in the claims. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

In some instances, components are described with reference to “ends” having a particular characteristic and/or being connected to another part. However, those skilled in the art will recognize that the present invention is not limited to components which terminate immediately beyond their points of connection with other parts. Thus, the term “end” should be interpreted broadly, in a manner that includes areas adjacent, rearward, forward of, or otherwise near the terminus of a particular element, link, component, member or the like. In methodologies directly or indirectly set forth herein, various steps and operations are described in one possible order of operation, but those skilled in the art will recognize that steps and operations may be rearranged, replaced, or eliminated without necessarily departing from the spirit and scope of the present invention.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together and in various possible combinations of various different features of different embodiments combined to form yet additional alternative embodiments, with all equivalents thereof.

While specific embodiments are discussed, it should be understood that this is done for illustration purposes only. A person skilled in the relevant art will recognize that other components and configurations may be used without parting from the spirit and scope of the disclosure. Thus, the above description and drawings are illustrative and are not to be construed as limiting. Numerous specific details are described to provide a thorough understanding of the disclosure. However, in certain instances, well-known or conventional details are not described in order to avoid obscuring the description.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance” or “in an aspect” or the like, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are described herein. Note that titles or subtitles may be used in the various embodiments for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Various features and advantages of the disclosure are set forth in the description above, and in part will be obvious from the description, or can be learned by practice of the herein disclosed principles. The features and advantages of the disclosure can be realized and obtained by means of the instruments and combinations particularly pointed out in the appended claims.

What is claimed:

1. A plasma system comprising:
a chamber containing at least one of a solid precursor or solid reactant material, the chamber in communication with a carrier gas line where the solid precursor or solid reactant material is captured by the carrier gas;
an electrode assembly including a first electrode and a second electrode, the first electrode and the second electrode proximally positioned to form an arc therebetween to generate a plasma with a plasma chamber operably coupled with the electrode assembly; and
a first channel in fluid communication with the carrier gas line, the channel positioned to deliver the carrier gas and the solid precursor or solid reactant at a controllable rate into the plasma chamber at the plasma generated therein.

2. The plasma system of claim 1 wherein the first electrode defines a first cylinder, and the second electrode defines a second cylinder circumferentially disposed about the first cylinder.

3. The plasma system of claim 1 wherein the first channel is defined along a cylindrical opening of the first cylinder.

4. The plasma system of claim 3 wherein a second channel is defined along a space between an outer surface of the first cylinder and the second cylinder circumferentially disposed about the first cylinder.

5. The plasma system of claim 4 wherein the first cylindrical electrode defines a first annular electrode end positioned with a second annular electrode end and defining a circular gap therebetween, the arc between formed between the first annular electrode end and the second annular electrode end across the gap to form a toroidal plasma within the plasma chamber.

6. The plasma system of claim 5 wherein the second channel is in fluid communication with the gap.

7. The plasma system of claim 5 wherein the first channel directs the carrier gas and solid precursor or solid reactant through a center region defined through the toroidal plasma when formed with the plasma chamber.

8. The plasma system of claim 7 wherein a terminal end port of the first channel is positioned at a center point of the circular gap.

9. The plasma system of claim 8 wherein the terminal end port is conical.

10. The plasma system of claim 5 wherein the first annular electrode end is beveled.

11. The plasma system of claim 10 wherein the second annular electrode end is beveled, the beveled portion of the second annular electrode end facing the beveled portion of the first annular electrode end.

12. The plasma system of claim 5 wherein at least one of the first electrode or the second electrode is adjustably supported to alter the circular gap formed between the first annular electrode end and the second annular electrode end.

13. The plasma system of claim 5 wherein the plasma chamber includes at least one port oriented to direct a third gas into the plasma chamber.

14. The plasma system of claim 1 wherein the first electrode is a graphite cathode, and the second electrode is a graphite anode.

15. The plasma system of claim 1 wherein a power supply is electrically coupled with the electrode assembly.

16. A method of producing solid-state electrolyte material comprising:
generating a plasma within a plasma chamber; and
controllably injecting a mixture of a carrier gas and solid-state electrolyte precursor powder or solid-state electrolyte reactant powder in the plasma chamber in the presence of the generated plasma to produce a solid-state electrolyte material.

17. The method of claim 16 further comprising controlling at least one of a pressure of the carrier gas and a flow rate of the carrier gas and the carrier gas is reactive or non-reactive.

18. The method of claim 16 wherein the mixture is injected through the generated plasma within the chamber, the generated plasma in the form of a toroid.

19. The method of claim 18 wherein a process occurring within the chamber includes vaporization of the solid-state electrolyte precursor powder or solid-state electrolyte reactant powder with an effective heating temperature from 70° C. to about 1200° C.

20. The method of claim 16 wherein a particle size of the solid-state electrolyte precursor powder or a powder size of the solid-state electrolyte reactant powder is in a range from 1 nm to 10 mm.

21. The method of claim 16 wherein the solid-state electrolyte precursor powder includes a lithium containing material, a phosphorus containing material, a sulfur containing material, or a halogen containing material.

22. The method of claim 21 wherein the lithium containing material comprises Li₂S, Li₂CO₃, or Li₂SO₄

23. The method of claim 21 wherein the sulfur containing material comprises elemental sulfur, Li₂S, GeS₂, or SiS₂.

24. The method of claim 21 wherein the phosphorus containing material or the halogen containing material comprises P₄S₁₀ or P₂S₅.

25. The method of claim 16 wherein the solid-state electrolyte precursor powder comprises at least one of Li₂S, P₃N₅, B₂S₃, Li₃N, or LiX₍₁₋ₐ₎Yₐ;
where X and Y include halogens selected from F, Cl, Br, and I, or pseudohalogens selected from BH₄, BF₄, OCN, CN, SCN, SH, NO, and NO₂; and
where 0≤a≤1.

26. The method of claim 16 wherein the solid-state electrolyte reactant powder comprises at least one of reactants Li₂SO₄, LiOH, P₂S₅, elemental phosphorus, H₂S, elemental sulfur, carbon, ammonium, elemental boron, LiX, or LiY, where X and Y include halogens selected from F, C, Br, and I, or pseudohalogens selected from BH₄, BF₄, OCN, CN, SCN, SH, NO, and NO₂.

27. The method of claim 16 wherein the solid-state electrolyte reactant powder includes lithium containing reactants, phosphorus containing reactants, or sulfur containing reactants.

28. The method of claim 27 wherein the lithium containing reactants include Li₂SO₄, LiOH, Li₂O, Li₂CO₃, LiNO₃, Li₃N, LiX, and LiY where X and Y include halogens selected from F, Cl, Br, and I, or pseudohalogens selected from BH₄, BF₄, OCN, CN, SCN, SH, NO, and NO₂.

29. The method of claim 27 wherein the lithium containing reactants include LiX₍₁₋ₐ₎Yₐ, wherein the X and Y include halogens, such as F, C, Br, or I, and/or pseudohalogens, such as BH₄, BF₄, OCN, CN, SCN, SH, NO, or NO₂ where 0≤a≤1.

30. The method of claim 27 wherein the phosphorus containing reactants include P₂S₅, P₂O₅, and elemental phosphorus.

31. The method of claim 27 wherein the sulfur containing reactants include H₂S and elemental sulfur.

32. The method of claim 27 wherein the solid-state electrolyte reactant powder further comprises other reactants including carbon, ammonium, and elemental boron.

33. The method of claim 16, wherein the solid-state electrolyte material comprises lithium rich anti-perovskite (LiRAP) materials.

34. The method of claim 16, wherein the solid-state electrolyte material comprises lithium-boron-sulfur (LBS) materials.

35. The method of claim 16, wherein the solid-state electrolyte material comprises sulfide electrolyte materials that contain phosphorus and/or a halogen (LPSX Materials).
